(19) United States
(12) Patent Application Publication
(10) Pub. No.: US 2016/0372393 A1
(43) Pub. Date: Dec. 22, 2016

(54) Laminar Structure, a Semiconductor Device and Methods for Forming Semiconductor Devices

(71) Applicant: Infineon Technologies AG, Neubiberg (DE)

(72) Inventors: Christian Kasztelan, Muenchen (DE); Alexander Breymesser, Villach (AT); Manfred Mengel, Bad Abbach (DE)

(21) Appl. No.: 15/182,983

(22) Filed: Jun. 15, 2016

(30) Foreign Application Priority Data
Jun. 18, 2015 (DE) 102015109764.8

(51) Int. Cl. H01L 23/29; H01L 21/56; H01L 21/3105; H01L 23/31

(52) U.S. Cl. CPC H01L 23/293; H01L 23/3121; H01L 21/565; H01L 21/3105

(57) ABSTRACT

A method for forming semiconductor devices includes placing a laminar structure having electrically insulating material arranged between a plurality of electrically conductive structures onto a surface of a semiconductor wafer comprising a plurality of semiconductor device structures. An electrically conductive structure of the plurality of electrically conductive structures is located adjacent to a semiconductor device structure of the plurality of semiconductor device structures. Each electrically conductive structure of the plurality of electrically conductive structures extends from a first surface of the laminar structure towards a second opposite surface of the laminar structure.

This application claims priority to German Application No. 10 2015 109 764.8, filed on Jun. 18, 2015, which application is hereby incorporated herein by reference in its entirety.

### TECHNICAL FIELD

Embodiments relate to semiconductor device structures, and in particular to a laminar structure, a semiconductor device and methods for forming semiconductor devices and methods for processing on wafer level.

### BACKGROUND

Trends in the field of power semiconductors may lead towards thinner wafers, a reduction in chip thickness and chip shrinkage. These may lead to challenges related to heat transfer losses generated in a semiconductor chip during normal operation and to fault events such as short circuits. Fault events in the order of microseconds may create local hotspots (e.g. a warming maximum or increase) which may exceed a junction temperature (Tj) of the semiconductor chip due to the design of the component. These fault events may lead to malfunctions and damages in the component, for example.

### SUMMARY

It is a demand to provide semiconductor devices with reduced instances of malfunction and/or increased reliability.

Such a demand may be satisfied by the subject matter of the claims.

Some embodiments relate to a method for forming semiconductor devices. The method comprises placing a laminar structure comprising electrically insulating material arranged between a plurality of electrically conductive structures onto a surface of a semiconductor wafer comprising a plurality of semiconductor device structures, so that an electrically conductive structure of the plurality of electrically conductive structures is located adjacent to a semiconductor device structure of the plurality of semiconductor device structures. Each electrically conductive structure of the plurality of electrically conductive structures extends from a first surface of the laminar structure towards a second opposite surface of the laminar structure.

Some embodiments relate to a laminar structure. The laminar structure comprises a plurality of electrically conductive structures and an electrically insulating material arranged between electrically conductive structures of the plurality of electrically conductive structures. Each electrically conductive structure of the plurality of electrically conductive structures extends from a first surface of the laminar structure towards a second opposite surface of the laminar structure.

Some embodiments relate to a semiconductor device. The semiconductor device comprises a semiconductor device structure formed in a semiconductor substrate. The semiconductor device further comprises a polymer-based or glass-based electrically insulating laminar structure laterally surrounding an electrically conductive structure.

Some embodiments relate to a method for forming a semiconductor device. The method comprises rolling a laminar structure onto a surface of a semiconductor wafer comprising a plurality of semiconductor device structures. At least a part of the laminar structure remains to form a part of the semiconductor device to be formed.

### BRIEF DESCRIPTION OF THE DRAWINGS

Some embodiments of apparatuses and/or methods will be described in the following by way of example only, and with reference to the accompanying figures, in which

FIG. 1 shows a flow chart of a method for forming semiconductor devices;

FIG. 2A shows a schematic illustration of a laminar structure and a semiconductor wafer;

FIG. 2B shows a schematic illustration of a process for forming semiconductor devices;

FIGS. 2C to 2E show schematic illustrations of various processes for aligning a laminar structure with a semiconductor wafer;

FIG. 2F shows a schematic illustration of a process for forming semiconductor devices;

FIG. 2G shows a cross-sectional schematic illustration of an interface between an electrically insulating material of a laminar structure and a semiconductor wafer;

FIG. 3 shows a flow chart of a method for forming semiconductor devices;

FIGS. 4A to 4D show schematic illustrations of a method for forming semiconductor devices by rolling a laminar structure;

FIGS. 5A to 5B show schematic illustrations of a laminar structure;

FIG. 6 shows a schematic illustration of a method for forming a laminar structure;

FIG. 7 shows a schematic illustration of a further method for forming a laminar structure;

FIG. 8 shows a schematic illustration of a further method for forming a laminar structure;

FIG. 9 shows a schematic illustration of a method for forming semiconductor devices;

FIG. 10 shows a schematic illustration of a semiconductor device;

FIG. 11 shows a schematic illustration of a semiconductor device with one laminar structure;

FIG. 12 shows a schematic illustration of a semiconductor device with two laminar structures;

FIG. 13 shows a schematic illustration of a semiconductor device with vias;

FIG. 14 shows a schematic illustration of a semiconductor device with a transistor structure; and

FIG. 15 shows a schematic illustration of a semiconductor device with a glass-based laminar structure.

### DETAILED DESCRIPTION OF ILLUSTRATIVE EMBODIMENTS

Various example embodiments will now be described more fully with reference to the accompanying drawings in which some example embodiments are illustrated. In the figures, the thicknesses of lines, layers and/or regions may be exaggerated for clarity.

Accordingly, while example embodiments are capable of various modifications and alternative forms, embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

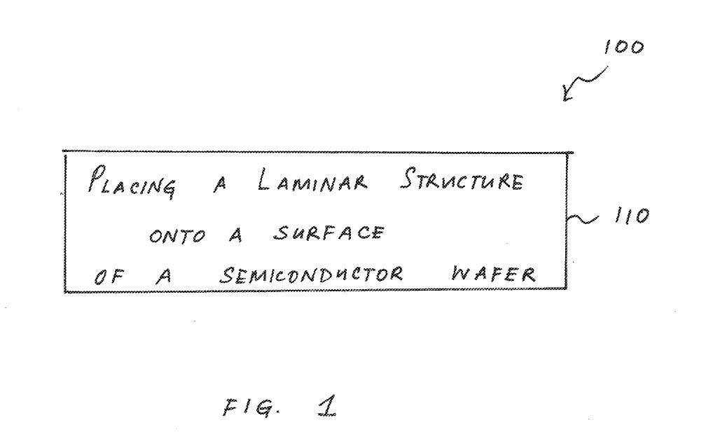

FIG. 1 shows a flow chart of a method 100 for forming semiconductor devices according to an embodiment.

The method 100 comprises placing 110 a laminar structure comprising electrically insulating material arranged between a plurality of electrically conductive structures onto a surface of a semiconductor wafer comprising a plurality of semiconductor device structures, so that an electrically conductive structure of the plurality of electrically conductive structures is located adjacent to a semiconductor device structure of the plurality of semiconductor device structures.

Each electrically conductive structure of the plurality of electrically conductive structures extends from a first surface of the laminar structure towards a second opposite surface of the laminar structure.

Due to the placing of the laminar structure comprising the plurality of electrically conductive structures and the electrically insulating material onto the surface of the semiconductor wafer, semiconductor devices may be more efficiently produced. For example, the process outputs for producing semiconductor devices may be increased. For example, the electrically conductive structures and the electrically insulating material may be deposited on the surface of the semiconductor wafer in a single application process by placing the laminar structure comprising both the plurality of electrically conductive structures and the electrically insulating material onto the surface of the semiconductor wafer. Furthermore, semiconductor devices (e.g. at wafer level or at chip level) which are more reliable may be produced due to the additional process stability obtained through a reduction of wafer warping, for example. Furthermore, the process for producing a plurality of semiconductor devices may be simplified as thick metals do not need to be deposited before the electrically insulating material, for example. Therefore, chip individualization processes may be less complex, for example. Furthermore, thick metallizations (or thick metal structures) may be implemented with low effort and/or low wafer bow, since the thickness of the electrically conductive structures may be selected in a wide range.

The laminar structure may be a thin plate, a sheet or a layer, for example. The first surface or second surface of the laminar structure may be a substantially even plane. In comparison to a basically vertical edge of the laminar structure, the first surface of the laminar structure and the second opposite surface of the laminar structure may each be a basically horizontal surface extending laterally. For example, a lateral dimension (e.g. a diameter or a length) of the main surface of the laminar structure may be more than 100 times larger (or more than 1000 times or more than 10000 times) than a distance between the first surface of the laminar structure and the second opposite surface of the laminar structure. The laminar structure may have an average lateral dimension (e.g. an average diameter or average length) of between 50 mm and 450 mm.

The laminar structure may have a maximal thickness of between 10 μm and 500 μm (or e.g. between 50 μm and 350 μm or e.g. between 50 μm and 150 μm), for example. The maximal thickness of the laminar structure may be a largest height of the laminar structure measured in a direction between the first (lateral) surface of the laminar structure and the second opposite (lateral) surface of the laminar structure.

The laminar structure may be in the form of a wafer. For example, the laminar structure may have substantially the same (or similar) shape as the semiconductor wafer on which the laminar structure is placed. For example, the laminar structure may have substantially the same size (e.g. a lateral dimension) as the semiconductor wafer. For example, a maximum difference between an average lateral dimension of the laminar structure and an average lateral dimension of the semiconductor wafer may lie between 1% and 5% of the average lateral dimension of the semiconductor wafer, for example.

The laminar structure may be in form of a rectangle. For example, the laminar structure may substantially cover the shape of a semiconductor wafer on which the laminar structure may be placed, for example. Additionally or optionally, the laminar structure may have a different size or different shape (e.g. rectangularly shaped) from the semiconductor wafer (e.g. which may be circularly shape). Protruding portions of the laminar structure may be removed (e.g. by stamping) after bonding the laminar structure to the semiconductor wafer, for example.

The laminar structure may be a substantially flat or even structure. For example, an average thickness of the electrically conductive structures and an average thickness of the electrically conductive material may be similar (or the same). For example, a deviation or variation of the average thickness of the electrically conductive structures and the average thickness of the electrically insulating material may be less than 10%, for example. Thus, a lateral surface of the laminar structure may have a topography variation of less than 10 μm over an area span of a semiconductor wafer (e.g. over an area span equal to or larger than a 200 mm diameter semiconductor wafer), for example. For example, a lateral surface of the laminar structure may have a topography variation of less than 2 μM over an area span of a semiconductor device or semiconductor die (e.g. over an area span equal to or larger than a 2 mm×2 mm semiconductor die).

The laminar structure may include electrically insulating material arranged between the plurality of electrically conductive structures. For example, the electrically insulating material may be formed in regions between neighboring electrically conductive structures of the plurality of electrically conductive structures. For example, the electrically insulating material may be located (directly) on sidewalls of the electrically conductive structures and may therefore laterally surround the electrically conductive structures. Optionally, the electrically insulating material may encapsulate or completely surround the electrically conductive structures except at a first surface of the laminar structure where the electrically conductive structures are exposed or free from the electrically insulating material.

The electrically insulating material may have an average thickness of between 10 μm and 500 μm (or e.g. between 50 μm and 350 μm or e.g. between 50 μm and 150 μm), for example. The average thickness of the electrically conductive structures may be an average thickness of the electrically insulating material measured in a direction between the first surface of the laminar structure and the second surface of the laminar structure, for example. The average thickness of the electrically insulating material may be a thickness of the electrically insulating material averaged over a region of interest of the laminar structure, for example.

The electrically insulating material of the laminar structure may include or may be a laminate material, for example. For example, the laminate material may be a polymer based laminate. For example, the polymer based laminate may include polyimide, polyacrylate or epoxy resin, or mixtures of these. Additionally or optionally, the electrically insulating material may include a laminate material and thermally conductive filler particles, for example. The thermally conductive filler particles may be embedded in the laminate material, for example. The thermally conductive filler particles may include or may be aluminum oxide particles, boron nitride particles, aluminum nitride particles or ceramic particles. The thermally conductive filler particles may be at least 90% of the volume of the electrically insulating material, for example. For example a ratio of thermally conductive filler particles to laminate material may be at least 90:10, for example.

Alternatively, the electrically insulating material of the laminar structure may include or may be glass, for example. For example, the glass may include or may be a low melting glass alloy (e.g. with melting points between 250 and 500° C.). Additionally or optionally, the electrically insulating glass may include thermally conductive filler particles and/or filler particles with low thermal expansion, for example.

The plurality of electrically conductive structures of the laminar structure may be continuous structures extending from the first surface of the laminar structure towards the second surface of the laminar structure. For example, the plurality of electrically conductive structures may be metallic structures (e.g. a metallic pillars or metallic layer stacks). For example, the electrically conductive structures may include copper (Cu), nickel (Ni) or molybdenum (Mo) or alloys of these materials. For example, the electrically conductive structures may be copper structures, nickel structures or molybdenum structures.

Optionally, the plurality of electrically conductive structures may be exposed at the first surface of the laminar structure and at the second surface of the laminar structure, for example. For example, each electrically conductive structure of the plurality of electrically conductive structures may extend from the first surface of the laminar structure to the second opposite surface of the laminar structure.

Optionally, the plurality of electrically conductive structures may be exposed at only the first surface of the laminar structure. Regions of the plurality of electrically conductive structures towards the second opposite surface of the laminar structure may be covered by the electrically insulating material of the laminar structure, for example.

Processes (e.g. grinding, brushing or polishing) to remove portions of the electrically insulating material covering the plurality of electrically conductive structures at the second surface of the laminar structure may be carried out after placing the laminar structure on the surface of the semiconductor wafer. These processes may expose the plurality of electrically conductive structures at the second surface of the laminar structure, for example. Each electrically conductive structure of the plurality of electrically conductive structures may provide an electrically conductive path between a first surface of the laminar structure and the second opposite surface of the laminar structure at least after the grinding, for example.

Each electrically conductive structure may be suitable for carrying a current signal or voltage signal from the first surface of the laminar structure towards (or to) the second opposite surface of the laminar structure, or between the first surface of the laminar structure and the second opposite surface of the laminar structure.

The electrically conductive structures may have an average thickness of between 10 μm and 500 μm (or e.g. between 50 μm and 350 μm or e.g. between 50 μm and 150 μm), for example. The average thickness of the electrically conductive structures may be an average height of the electrically conductive structures measured in a direction between the first surface of the laminar structure and the second surface of the laminar structure, for example. The average thickness of the electrically conductive structures may be a thickness of the electrically conductive structures averaged over a region of interest of the laminar structure, for example.

An average thickness of the electrically conductive structures and an average thickness of the electrically insulating material may be similar (or the same). For example, a deviation or variation of the average thickness of the electrically conductive structures and the average thickness of the electrically insulating material may be less than 10%, for example. Thus, a lateral surface of the laminar structure may have a topography variation of less than 10 μm over an area span of a semiconductor wafer (e.g. over an area span equal to or larger than a 200 mm diameter semiconductor wafer), for example. For example, a lateral surface of the laminar structure may have a topography variation of less than 2 μm over an area span of a semiconductor device or semiconductor die (e.g. over an area span equal to or larger than a 2 mm×2 mm semiconductor die).

Each electrically conductive structure of the plurality of electrically conductive structures may have a maximal lateral dimension of more than 10 μm (or e.g. more than 15 μm or e.g. more than 20 μm), for example. The maximal lateral dimension of an electrically conductive structure may be a length or diagonal length of the electrically conductive structure measured in a direction parallel to a lateral surface of the laminar structure, for example.

An arrangement (or layout) of the plurality of electrically conductive structures in the laminar structure may correspond to an arrangement of a plurality of electrical contact structures of the plurality of semiconductor device structures at the first surface of the semiconductor wafer, for example. For example, a maximum lateral dimension of an electrically conductive structure of the plurality of electrically conductive structures may be equal to or proportional to a maximum lateral dimension of its corresponding electrical contact structure at the first surface of the semiconductor wafer. Additionally or optionally, a maximum lateral dimension of an electrically conductive structure of the plurality of electrically conductive structures may be larger (e.g. not smaller) than a maximum lateral dimension of its corresponding electrical contact structure at the first surface of the semiconductor wafer by a scaling constant, for example. For example, the scaling constant may lie between 1% and 5%, for example. For example, a maximum lateral dimension of an (or each) electrically conductive structure of the plurality of electrically conductive structures may be larger than a maximum lateral dimension of its corresponding electrical contact structure at the first surface of the semiconductor wafer by less than 5 μm, for example.

Additionally or optionally, a spacing or distance between electrically conductive structures in the laminar structure may be equal to or proportional to a spacing or distance a plurality of electrical contact structures of the plurality of semiconductor device structures at the first surface of the semiconductor wafer, for example. For example, a distance between neighboring electrically conductive structures in the laminar structure may be less than 20 μm (or e.g. less than 10 μm or e.g. less than 2 μm).

The semiconductor wafer may include a semiconductor substrate material (e.g. a semiconductor substrate wafer), for example. For example, the semiconductor substrate material may be a silicon-based semiconductor substrate material, a silicon carbide-based semiconductor substrate material, a gallium arsenide-based semiconductor substrate material or a gallium nitride-based semiconductor substrate material.

The semiconductor wafer may further include metal layers, insulation layers and/or passivation layers on a main (front) surface (and/or at a back side surface) of the semiconductor wafer or on a surface of one of these layers, for example.

The semiconductor wafer may have at least one surface (e.g. a front surface or a back surface). The front surface or back surface of the semiconductor wafer may be a substantially even plane (e.g. neglecting unevenness of the semiconductor structure due to the manufacturing process and trenches). For example, a lateral dimension (e.g. a diameter) of the main surface of the semiconductor wafer may be more than 100 times larger (or more than 1000 times or more than 10000 times) than a maximal height of structures on the main surface. In comparison to a basically vertical edge of the semiconductor wafer, the main surface or chip front side of the chip may be a basically horizontal surface extending laterally. For example, the lateral dimension (e.g. a diameter) of the main surface of the semiconductor wafer may be more than 100 times larger (or more than 1000 times or more than 10000 times) than a vertical dimension of a vertical edge of the semiconductor wafer, for example. An average thickness of the semiconductor wafer may be less than 800 μm (or e.g. less than 200 μm or e.g. less than 100 μm), for example. An average lateral dimension (e.g. an average diameter or length) of the main surface of the semiconductor wafer may lie between 50 mm and 450 mm or more (or e.g. be substantially 150 mm, or 200 m or 300 m), for example.

A front surface (or main surface or front side) of the semiconductor wafer may be a surface of the semiconductor wafer towards metal layers, insulation layers and/or passivation layers on top of the main surface of the semiconductor wafer or a surface of one of these layers. For example, the front surface of the semiconductor wafer may be a surface of the semiconductor wafer at which more (or a majority of) active elements of the semiconductor device structures are formed. For example, more complex structures may be located at the semiconductor wafer front side than at the semiconductor wafer back side. For example, for power transistor structures, a main surface of the semiconductor wafer may be a side or surface of the semiconductor wafer at which a first source/drain region and a gate region may be formed.

A back side surface (or back side of the semiconductor wafer may be a surface at which a second source/drain region is formed. For example, for power transistor structures, a back side surface of the semiconductor wafer may be a side or surface of the semiconductor wafer at which a second source/drain region may be formed.

The semiconductor wafer may include at least one (or e.g. a plurality) of semiconductor device structures which may be arranged (or formed) at least partially in the semiconductor wafer. A semiconductor device structure may be arranged in a semiconductor die of the semiconductor wafer, for example. Each semiconductor wafer may include one or more semiconductors dies or semiconductor device structures (e.g. more than 100, or more than 1000 or more than tens of thousands of semiconductor dies or semiconductor device structures, for example. The plurality of dies may be separated by scribe line regions or kerf regions of the semiconductor wafer, for example.

Each semiconductor device structure may include electrical circuitry having one or more electrically conductive active elements. For example, an electrically conductive active element may be modified or biased to a different electrical state by an applied external bias (e.g. an applied voltage or applied current signal), for example. The electrically conductive active elements of the semiconductor device structure may be formed at least partially in the semiconductor wafer (e.g. as doping regions with varying or different conductivity types) or may be additional layers incorporated, deposited or grown on the semiconductor wafer, for example. The electrically conductive active elements of the semiconductor device structure may be formed at an active area of the semiconductor device structure. The active area of the semiconductor device structure may be formed in a substantially central region of a semiconductor die of the semiconductor wafer, for example.

An active element of the semiconductor device structure may be an electrically doped region of a diode structure or a transistor structure, for example. For example, an active element of the semiconductor device structure may include or may be a source or emitter region of a transistor structure, a drain or collector region of a transistor structure, a body region of a transistor structure, or a gate region of a transistor structure, for example. For example, an active element of the semiconductor device structure may include a first doping region (e.g. an anode region) of a diode structure or a second doping region (e.g. a cathode region) of the diode structure.

The semiconductor device structure may include a metal oxide semiconductor field effect transistor (MOSFET) structure, a bipolar junction transistor (BJT) structure, an insulated gate bipolar transistor (IGBT) structure, a diode structure or a thyristor structure, for example.

Each semiconductor device structure (or semiconductor die) may include at least one electrical contact structure. An (or each) electrical contact structure may include or may be an electrically conductive contact region, which may be electrically connected to at least one electrically active element of the integrated circuit of the semiconductor device structure. An (or each) electrical contact structure may be formed on a side or surface of the semiconductor wafer, for example. An electrical contact structure may be connected to the electrically conductive active elements directly or optionally via one or more interconnects or intermediate layers, for example. The electrical contact structure may be further used to provide an electrically connection between the at least one electrically active element of the semiconductor device structure of the chip and an external structure and/or external circuit.

The electrical contact structures may include electrically conductive material formed in predetermined positions over the semiconductor wafer first surface (or front side). For example, a first electrical contact structure may include electrically conductive material, which may be in electrical contact with a first active element of a semiconductor device structure of a semiconductor die. This may be a first source/drain region of a transistor structure, for example. For example, a second electrical contact structure may include electrically conductive material, which may be in electrical contact with a second active element of the semiconductor device structure of the semiconductor die. This may be a gate region of the transistor structure, for example. The semiconductor wafer second (opposite) surface may also include a further electrical contact structure, which may be in electrical contact with a further active element of the semiconductor device structure of the semiconductor die. The further electrical contact structure may be a backside metallization layer for a second source/drain region of the transistor structure, for example.

Placing the laminar structure onto the surface of the semiconductor wafer may include positioning the laminar structure with respect to the surface of the semiconductor wafer so that a lateral surface of the laminar structure is arranged adjacent to the lateral surface of the semiconductor wafer. It may be understood that placing the laminar structure onto the surface of the semiconductor wafer may include arranging the laminar structure above (on top of) the surface of the semiconductor wafer or below (underneath) the surface of the semiconductor wafer, for example.

Optionally, placing the laminar structure onto the surface of the semiconductor wafer may further include rolling the laminar structure onto the surface of the semiconductor wafer. In this case, the laminar structure may include a flexible sheet, such as a flexible laminate sheet, for example.

Placing the laminar structure onto the surface of the semiconductor wafer may include arranging the laminar structure with respect to the semiconductor wafer so that an (or each) electrically conductive structure of the plurality of electrically conductive structures may be located adjacent to a semiconductor device structure of the plurality of semiconductor device structures. For example, an (or each) electrically conductive structure of the plurality of electrically conductive structures may be located (directly) adjacent to an electrical contact structure of the plurality of semiconductor device structures. Placing the laminar structure onto the surface of the semiconductor wafer may include arranging the electrically conductive structure of the laminar structure onto an electrical contact structure arranged in an active area of the semiconductor device, for example. As a maximum lateral dimension of the electrically conductive structure may be larger than or equal to a maximum lateral dimension of the electrical contact structure, it may be possible that a portion of an electrically conductive structure may be located outside of the active area of the semiconductor device. The electrically conductive structure may be located outside of the active area of the semiconductor device by less than 50 μm (or e.g. less than 10 μm or less than 5 μm), for example. For example, a lateral distance dimension of the electrically conductive structure formed in an edge termination region (outside the active area) of the semiconductor device may be less than 50 μm (or e.g. less than 10 μm or less than 5 μm).

Placing the laminar structure onto the surface of the semiconductor wafer may include arranging a first electrically conductive structure of the laminar structure onto a first electrical contact structure of the semiconductor device located at the (first) surface of the semiconductor wafer. The first electrical contact structure may be in electrical connection with a source region (or emitter region) of a semiconductor device transistor structure or a first doping region (e.g. an anode region) of a semiconductor device diode structure, for example. For example, in a power transistor structure, the first electrical contact structure may be electrically connected to an active first source/drain region of a MOSFET transistor structure or an active emitter region of a BJT transistor structure.

Placing the laminar structure onto the (first) surface of the semiconductor wafer may further include arranging a second electrically conductive structure of the laminar structure onto a second electrical contact structure of the semiconductor device located at the first surface of the semiconductor wafer. The second electrical contact structure may be in electrical connection with a gate region (or a base region) of the semiconductor device transistor structure, for example. For example, the second electrical contact structure may be in electrical connection with a gate region of a MOSFET transistor structure or a base region of a BJT transistor structure.

Placing the laminar structure onto the surface of the semiconductor wafer may further include arranging the electrically insulating material of the laminar structure at (or onto) edge termination regions (or at least part of an edge termination region) of the semiconductor devices, for example. An edge termination region of the semiconductor device structure may be arranged around an active area of the semiconductor device, for example. For example, an edge termination region of the semiconductor device structure may laterally surround an active area of the semiconductor device structure. For example, an edge termination region of the semiconductor device structure may be formed around an outer periphery or circumference of an active area of the semiconductor device structure. At least part of the edge termination region may be formed between the active area of the semiconductor device structure and a scribe line region of the semiconductor device structure, for example. A lateral dimension of the edge termination region (e.g. a distance measured between the active area and the scribe line region) may be at least 10 μm (or e.g. at least 50 μm), for example.

Placing the laminar structure onto the surface of the semiconductor wafer may further include arranging the electrically insulating material of the laminar structure at (or onto) scribe line regions of the semiconductor wafer between the plurality of semiconductor devices, for example. The scribe line regions may also be referred to as kerf regions of the semiconductor wafer, and may be regions of the semiconductor wafer through which dicing of the individual dies may be carried out, for example.

Placing the laminar structure onto the surface of the semiconductor wafer may include aligning the laminar structure and the semiconductor wafer using at least one alignment structure formed in at least one of the laminar structure and the semiconductor wafer. The alignment process may be carried out so that an (or each) electrically conductive structure encapsulates (or covers) (e.g. fully covers) an electrical contact structure of the semiconductor device structure, for example. The at least one alignment structure of the laminate structure may include or may be a positioning hole, notch or recess, for example. Alternatively or optionally, an alignment structure of the laminate structure may include or may be an electrically conductive structure. Alternatively or optionally, an alignment structure of the semiconductor wafer may include or may be a positioning pattern or a positioning die (e.g. a blank die) formed in the semiconductor wafer, for example.

Method 100 may further include joining (e.g. soldering) the plurality of electrically conductive structures of the laminar structure to electrical contact structures of the plurality of semiconductor device structures. The soldering may be carried out after arranging or aligning the laminar structure and the semiconductor wafer, for example. The electrically conductive structures of the laminar structure may be diffusion soldered to the electrical contact structures of the semiconductor device structures, for example.

Optionally, the plurality of electrically conductive structures of the laminar structure may include solder material (e.g. a gold-tin alloy or a copper-tin alloy) formed on surface regions of the plurality of electrically conductive structures, for example. The solder material may be deposited or located at surface regions of the electrically conductive structures at the first surface of the laminar structure and/or at the second opposite surface of the laminar structure. The solder material may be deposited onto the surface regions of the electrically conductive structures before placing the laminar structure onto the surface of the semiconductor wafer, for example. Optionally, the method 100 may include depositing the solder material onto the surface regions of the electrical contact structures of the semiconductor devices before placing the laminar structure onto the surface of the semiconductor wafer, for example.

Optionally, instead of (or in addition to) depositing solder material on the surface regions of the electrically conductive structures or on the surface regions of the electrical contact structures, method 100 may include placing a die-attach wafer between the laminar structure and the semiconductor wafer. The die-attach wafer may include a plurality of die-attach regions, each region including bonding material, for example. An arrangement (or layout) of the plurality of die-attach regions in the die-attach wafer may correspond to an arrangement of a plurality of electrical contact structures of the plurality of semiconductor device structures at the surface of the semiconductor wafer, for example. The die-attach wafer may be aligned with the laminar structure and the semiconductor wafer so that a die-attach region may be arranged between an electrically conductive structure of the laminar structure and an electrical contact structure of the semiconductor device structure, for example.

The method 100 may include providing heat and/or pressure (e.g. in the soldering process) to a stack arrangement comprising the semiconductor wafer and the laminar structure (and optionally the die-attach wafer), to join the laminar structure and the semiconductor wafer (and optionally the die-attach wafer). The method may include joining the electrically conductive structures of the laminar structure to electrical contact structures of the plurality of semiconductor devices and joining the electrically insulating material of the laminar structure to the surface of the semiconductor wafer (or edge termination regions of the plurality of semiconductor devices) simultaneously, for example. The heat provided may harden or cure the electrically insulating material of the laminar structure, for example. For example, the laminar structure may be laminated to the surface of the semiconductor wafer, so that the laminar structure may be hermetically adhered to the surface of the semiconductor wafer, for example.

Although only one (first) laminar structure being placed over a first surface of the semiconductor wafer has been described, it may be understood that the method 100 may also include forming a (second or further) laminar structure over a second surface of the semiconductor wafer. For example, method 100 may further include placing a further (or second) laminar structure including electrically insulating material arranged between a plurality of electrically conductive structures onto a opposite (second) surface of the semiconductor wafer including the plurality of semiconductor devices, so that an electrically conductive structure of the plurality of electrically conductive structures of the second laminar structure is located adjacent to a semiconductor device structure of the plurality of semiconductor device structures. For example, the electrically conductive structure of the second laminar structure may be formed on an opposite side of the semiconductor device structure to the first electrically conductive structure and/or second electrically conductive structure of the first laminar structure.

Similarly to the first laminar structure, each electrically conductive structure of the plurality of electrically conductive structures of the second laminar structure may provide an electrically conductive path between a first surface of the second laminar structure and a second opposite surface of the second laminar structure. For example, each electrically conductive structure of the plurality of electrically conductive structures of the second laminar structure may extend from a first surface of the second laminar structure towards a second opposite surface of the second laminar structure.

The second laminar structure may be similar to the first laminar structure, except that an arrangement (or layout) of the plurality of electrically conductive structures in the second laminar structure may correspond to an arrangement of a plurality of electrical contact structures (backside metallizations) of the plurality of semiconductor device structures at the second opposite surface of the semiconductor wafer, for example.

Placing the second laminar structure onto the second surface of the semiconductor wafer may include arranging a first electrically conductive structure of the second laminar structure onto a third electrical contact structure of the semiconductor device structure located on the second surface of the semiconductor wafer. The third electrical contact structure may be in electrical connection with a drain region (or collector region) of the semiconductor device transistor structure or a second doping region (e.g. a cathode region of a semiconductor device diode structure. For example, in a power transistor structure, the third electrical contact structure may be electrically connected to an active second source/drain region of a MOSFET transistor structure or an active collector region of a BJT transistor structure.

Alternatively or optionally, the semiconductor wafer may be arranged between the first laminar structure and the second laminar structure, and the first laminar structure and the second laminar structure may be joined (e.g. in a solder process) or laminated to the surface of the semiconductor wafer simultaneously or in a single joining (soldering) process, for example.

Optionally, the first laminar structure may be placed on the first surface of the semiconductor wafer and joined (or laminated) to the first surface of the semiconductor wafer before placing the second laminar structure on the second surface of the semiconductor wafer and joining (or laminating) the second laminar structure to the second surface of the semiconductor wafer, for example.

Optionally, the method 100 may further include thinning (or grinding) the semiconductor wafer from a back side (e.g. a second surface) of the semiconductor wafer to a desired thickness before placing the second laminar structure onto the second surface of the semiconductor wafer, for example.

The method 100 may further include subsequently, separating (or dicing) the semiconductor wafer to separate the individual semiconductor dies (each including a semiconductor device structure) of the semiconductor wafer from each other. Dicing may be carried out by dicing (e.g. sawing or slicing) through the electrically insulating material arranged on the scribe line regions of the semiconductor wafer (and through the scribe line regions of the semiconductor wafer) to form a plurality of individualized semiconductor devices. As the scribe line regions of the semiconductor wafer are free from metallic structures, dicing may be carried out without dicing through metallic structures, for example. This may lead to an easier dicing process, for example.

The method 100 may result in chip shrinkage and chip thickness design reduction without losing the electrical operation stability or reliability from short circuits. Furthermore, the generated heat losses may be more efficiently transferred over the chip front and back side, and further to the package and the surroundings (e.g. external environment). Thick copper or molybdenum metal stacks may be arranged on the chip front side and back side, for example. These stacks may have a very high thermal (and electrical) conductivity (which may be important in normal operation) and a high heat capacity. For failures in the microsecond region, the latter may help to cache or temporarily store the heat generated by the chip, for example.

The method 100 may provide thick metal stacks on the chip front side and back side on a wafer level through a laminar structure (e.g. a laminate), for example. The laminate may be formed from an electrically isolating matrix and metal structure, which may fit with the form (shape) and size of the respective chip metallization (e.g. front side and back side contact pads). Electrically insulating material and the metal areas of the laminar structure (e.g. lamination sheet or glass-metal wafer) may form a plane, and may have the same thickness (e.g. between 10 μm to 110 μm), for example.

The method 100 may provide a structured metal layer (Cu, Ni or Mo) having a thickness of between 10 μm and 500 μm (or e.g. between 50 μm and 350 μm or e.g. between 50 μm and 150 μm), over a chip front side and back side over the active area. This may simplify the individualization process of chips, which may otherwise be challenging if unstructured metal layers were to be formed (completely) on a surface of the chip back side. The method 100 may increase or improve the cooling performance of the chip by varying the thickness of the laminate from 10 μm to 150 μm. For example, thicker metal stacks may improve heat conduction away from the semiconductor device structure. The method 100 may increase the process stability through reduction of wafer bows (e.g. warping) by depositing layers on the chip top (e.g. front) and bottom (e.g. back) side at the same time, for example. The method 100 may simplify the chip individualization process, as separation does not need to be carried out through the thick or hard metals, for example. The method 100 may increase the process output through the possibility of separating the lamination and the joining process as thick metals do not need to be deposited first, for example.

The method 100 may avoid process on wafer or chip surfaces such as sintering of Mo (or Cu) plates, disk or pads, metal sputter processes, galvanic deposition process, three dimensional metal printing processes and glass frame with additional fillings of copper to produce thicker metal layers on the chip surface. Time intensive and expensive sintering and sputter processes may be avoided, for example. Sputter processes and galvanic deposition processes which allow maximum stacks of 20 μm may be avoided, for example. Strong warping in the wafer and a large wafer bow after the cooling due to sintering and galvanic processes may be avoided, for example. Furthermore, warping associated with increasingly thick layers may be avoided and further layers on the chip front and back side to reduce stress are not necessarily possible, for example. Processes (e.g. print processes) which lead to outgassing from the solution in which the metal particles are dissolved (e.g. permanent ink) may be avoided, for example. Furthermore, printing and drying processes which may lead to brittleness may be avoided, for example. Time intensive, expensive and imprecise processes using glass frames and copper filling processes may be avoided, for example. In particular, thick unstructured metal layers on the wafer back side, which increases complexity in the process of individualizing chips by sawing may be avoided, for example.

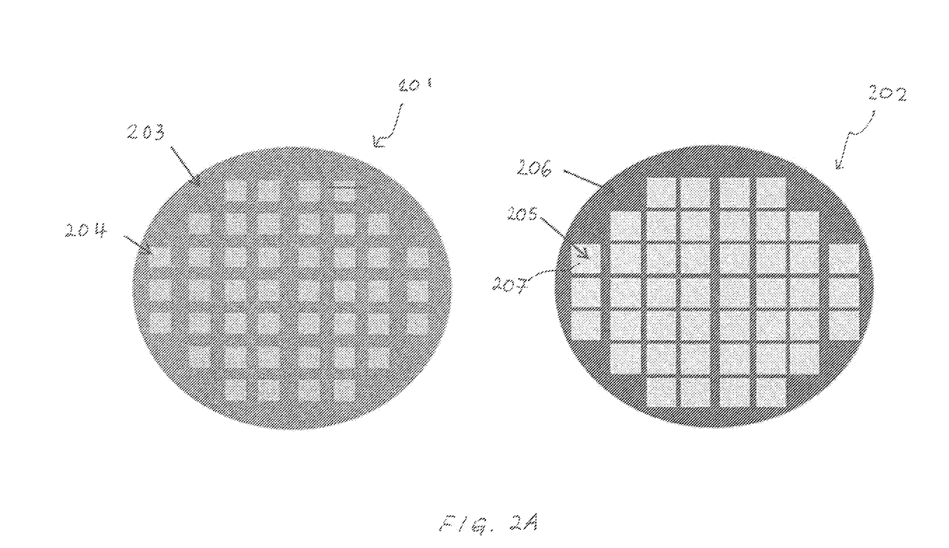

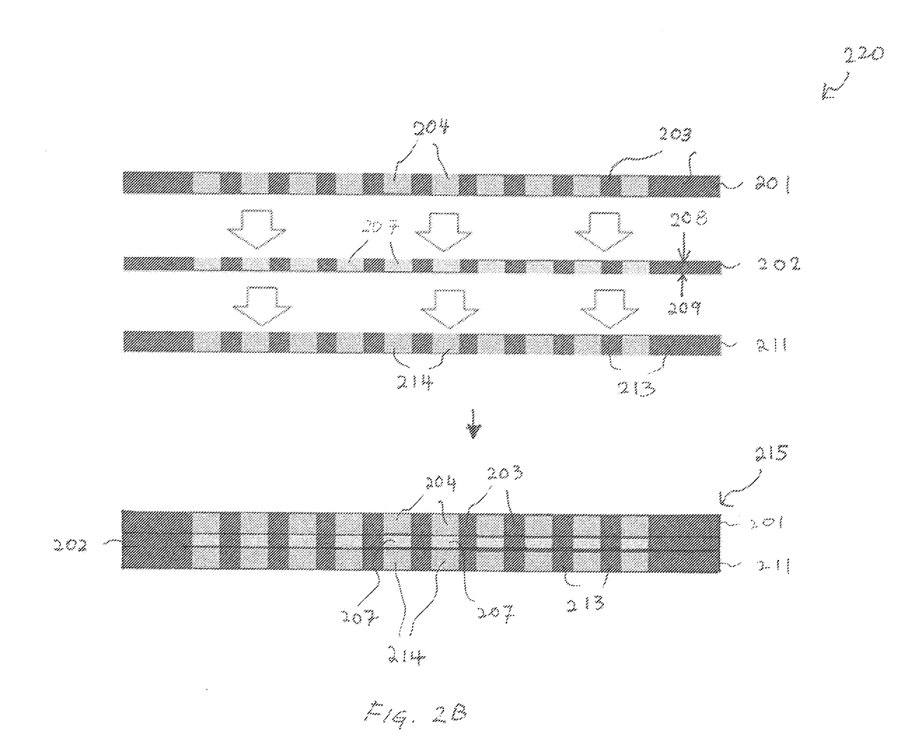

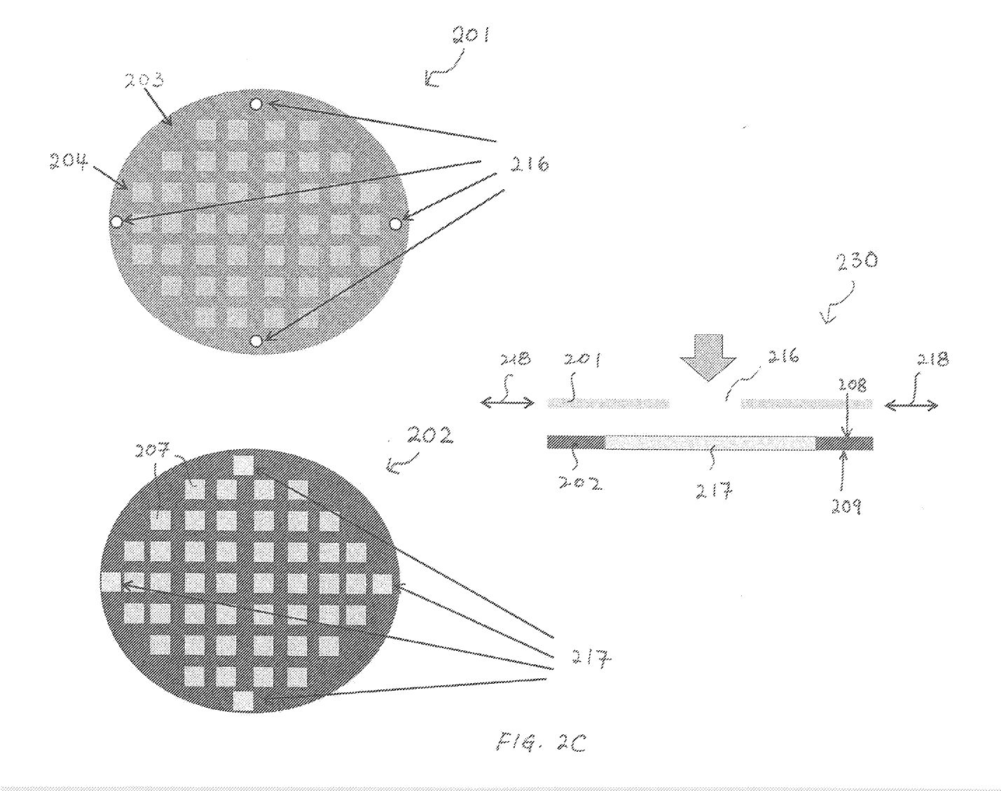

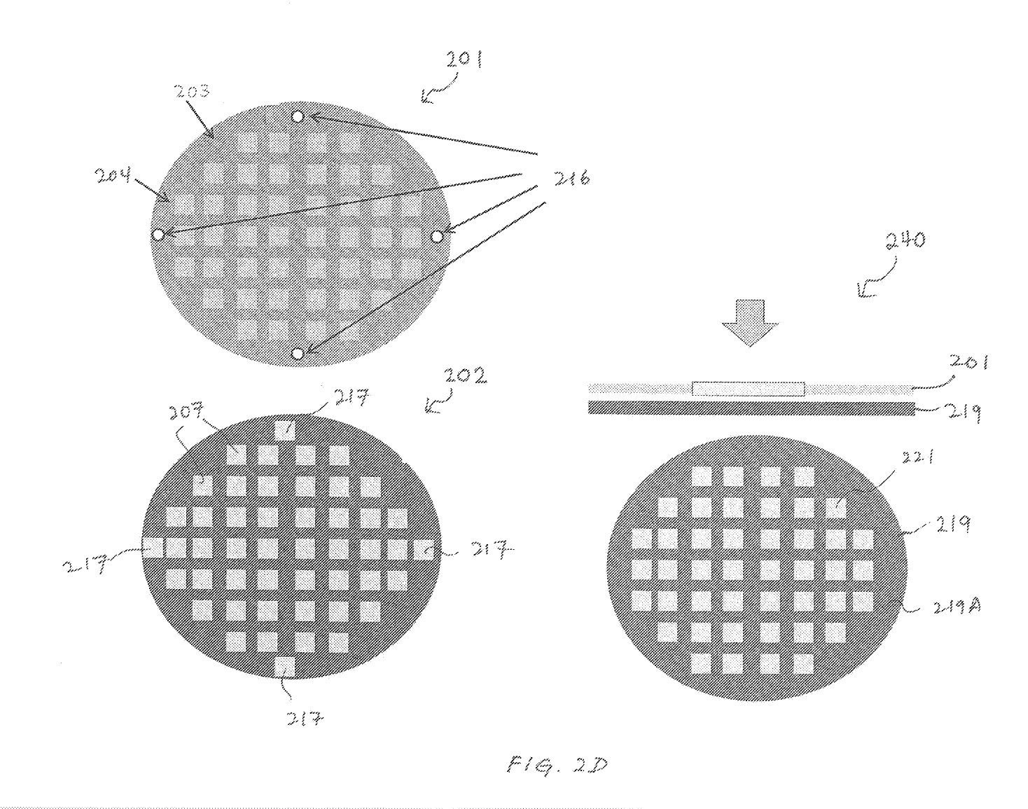

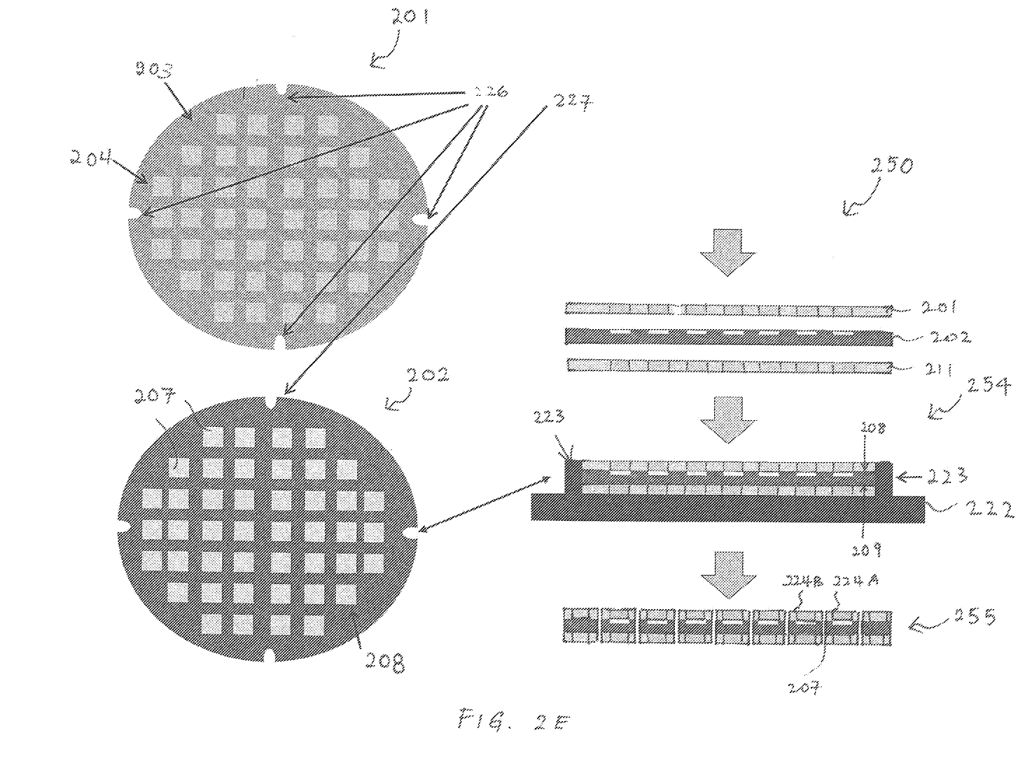

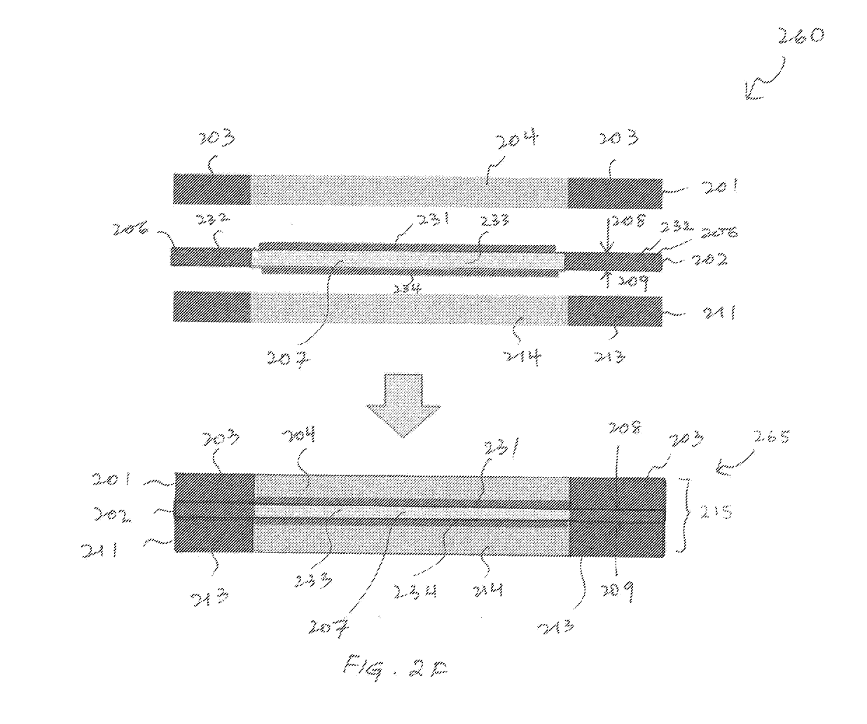

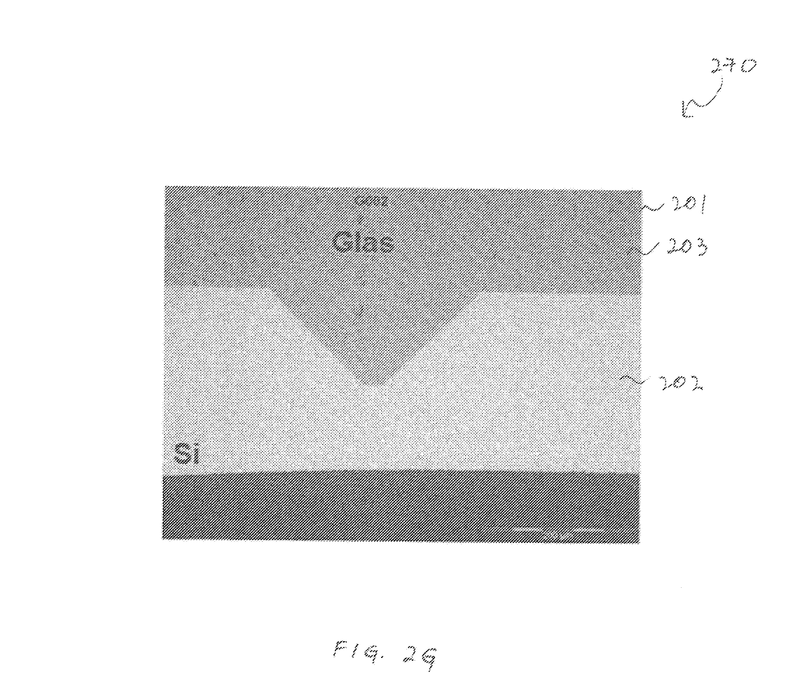

FIG. 2A shows a schematic illustration (top view) of the laminar structure 201 (on the left side) described in connection with FIG. 1. FIG. 2A further shows a schematic illustration (top view) of the semiconductor wafer 202 (on the right side) described in connection with FIG. 1.

The laminar structure 201 may be in the form of a wafer, for example. For example, the laminar structure 201 may include an electrically insulating material 203 (e.g. laminate or glass) in the form of a wafer. The laminar structure 201 may further include a plurality of electrically conductive structures 204 (e.g. metal islands), for example. The electrically insulating material 203 may be arranged between a plurality of neighboring electrically conductive structures 204. For example, each electrically conductive structure 204 may be laterally surrounded by the electrically insulating material 203, for example.

The semiconductor wafer 202 (e.g. a silicon wafer) may include a plurality of semiconductor dies 205, for example. The semiconductor dies 205 may each include a semiconductor device structure 207 formed in the semiconductor die 205, for example. The scribe line regions 206 of the semiconductor wafer may be located between neighboring semiconductor dies 205, for example.

More details and aspects are mentioned in connection with the embodiments described above or below. The embodiments shown in FIG. 2A may comprise one or more optional additional features corresponding to one or more aspects mentioned in connection with the proposed concept or one or more embodiments described above (e.g. FIG. 1) or below (e.g. FIGS. 2B to 15).

FIG. 2B shows a schematic illustration (cross-sectional view) of a process 220 for forming semiconductor devices according to an embodiment.

The process 220 may be similar to the method described in connection with FIG. 1, for example.

The (first) laminar structure 201 (e.g. a glass-metal wafer, or e.g. a laminate-metal wafer) comprising electrically insulating material 203 arranged between a plurality of electrically conductive structures 204 may be placed onto a first surface 208 of the semiconductor wafer 202 (e.g. a normal wafer) comprising a plurality of semiconductor device structures 207. An electrically conductive structure 204 of the plurality of electrically conductive structures 204 may be arranged adjacent to a semiconductor device structure 207 at the first surface 208 of the semiconductor wafer 202, for example.

The (further or second) laminar structure 211 (e.g. a glass-metal wafer, or e.g. a laminate-metal wafer) comprising electrically insulating material 213 arranged between a plurality of electrically conductive structures 214 may be placed onto a second opposite surface 209 of the semiconductor wafer 202. An electrically conductive structure 214 of the second laminar structure 211 may be arranged or located adjacent to the semiconductor device structure 207 at the second surface 209 of the semiconductor wafer 202, for example.

The semiconductor wafer 202 arranged between the first laminar structure 201 and the second laminar structure 211 may form a sandwich stack 215 for example. Due to the formation of the sandwich stack 215, the plurality of electrically conductive structures 204 of the first laminar structure 201 may be arranged adjacent to a plurality of semiconductor device structures 207 of the semiconductor wafer 202 in a single (parallel) process, for example. Furthermore, the plurality of electrically conductive structures 214 of the second laminar structure 211 may be arranged adjacent to the plurality of semiconductor devices 207 of the semiconductor wafer 202 in a single (parallel) process, for example. For example, the plurality of electrically conductive structures 204 of the first laminar structure 201 may be respectively arranged onto corresponding electrical contact structures of the plurality of semiconductor device structures 207 on the first surface 208 of the semiconductor wafer 202 in a single (parallel process). Furthermore, the plurality of electrically conductive structures 214 of the second laminar structure 211 may be respectively arranged onto corresponding electrical contact structures of the plurality of semiconductor device structures 207 on the second surface 209 of the semiconductor wafer 202 in a single (parallel process).

Alternatively or optionally, only one of the first laminar structure 201 and the second laminar structure 211 may be deposited onto a surface of the semiconductor wafer 202. This may be carried out to manufacture an extremely thin silicon layer or a thin semiconductor device package, for example.

More details and aspects are mentioned in connection with the embodiments described above or below. The embodiments shown in FIG. 2B may comprise one or more optional additional features corresponding to one or more aspects mentioned in connection with the proposed concept or one or more embodiments described above (e.g. FIGS. 1 to 2A) or below (e.g. FIGS. 2C to 15).

FIG. 2C shows a schematic illustration of a process 230 for aligning the laminar structure with the semiconductor wafer according to an embodiment.

The laminar structure 201 (which may include the plurality of electrically conductive structures 204) may be accurately positioned relative to the semiconductor wafer 202, for example. The electrically conductive structures 204 may be metal islands (e.g. copper islands) at least partially surrounded by the electrically insulating material 203 (e.g. laminate or glass).

Alignment structures 216 (e.g. positioning holes) may be formed in the (laminate or glass) laminar structure 201, for example. The (laminate-based or glass-based) laminar structure 201 may be in the form of a wafer (e.g. semiconductor wafer 202), for example. Alignment structures 217 (e.g. dead dies) may be formed at edge regions of the semiconductor (e.g. Si) wafer. The laminar structure 201 may be positioned or aligned 230 with respect to the semiconductor wafer 202 so that the positioning holes 216 of the laminar structure are aligned with the alignment structures 217 of the semiconductor wafer 202, for example. A position of the laminar structure 201 (and/or the semiconductor wafer 202) may be adjusted in a lateral direction 218 (e.g. to adjust an x-y position of the laminar structure with respect to the semiconductor wafer 202), for example. The lateral direction 218 may be a direction parallel to a main surface (e.g. 208) of the semiconductor wafer 202 (or to the largest surface of the laminar structure 201), for example.

More details and aspects are mentioned in connection with the embodiments described above or below. The embodiments shown in FIG. 2C may comprise one or more optional additional features corresponding to one or more aspects mentioned in connection with the proposed concept or one or more embodiments described above (e.g. FIGS. 1 to 2B) or below (e.g. FIGS. 2D to 15).

FIG. 2D shows a schematic illustration of a further process 240 for aligning the laminar structure with the semiconductor wafer according to an embodiment.

The process 240 may be similar to the process described in connection with FIG. 2C.

The process 240 may include arranging a structured die-attach wafer 219 between the semiconductor (actual) wafer 202 with semiconductor device structures 207 and the laminar structure 201 (e.g. the wafer with metal islands/electrically conductive structures 204), for example. The cross-sectional view (in 240) shows a sandwich stack of a laminar structure 201 with copper islands (on top) and the die attach wafer 219 placed below the laminar structure 201. The die attach wafer 219 may be placed between the laminar structure 201 and the semiconductor wafer 202, for example.

For example, the die attach wafer 219 may include a plurality of die attach regions 221 (or islands) formed in (or on) a substrate. The die attach regions 221 may include or consist of sinter paste (e.g. sinter paste bond metal). An arrangement of the die attach regions 221 of the die attach wafer 219 may be based on (e.g. may correspond to) the arrangement of electrically conductive structures 204 in the laminar structure 201, for example. For example, an arrangement of the die attach regions 221 of the die attach wafer 219 may correspond to an arrangement of electrical contact structures of the semiconductor device structures 207 located at the first surface 208 of the semiconductor wafer 202. An isolating material 219A (which may be e.g. polymer or glass) may be formed between (or surround) the die attach regions 221 of the die attach wafer 219, for example.

The semiconductor wafer 202, the die attach wafer 219 and the laminar structure 201 may be arranged in a three-wafer stack. The die attach wafer 219 may be arranged with respect to the semiconductor wafer 202 so that respective die attach regions 221 of the plurality of die attach regions 221 of the die attach wafer 219 are arranged onto corresponding electrical contact structures of the semiconductor device structures 207 of the semiconductor wafer 202, for example. Furthermore, the laminar structure 201 may be arranged with respect to the die attach wafer 219 so that a plurality of electrically conductive structures 204 of the laminar structure 201 are arranged onto corresponding die attach regions 221 of the die attach wafer, for example. In this way, a fully adhered (or fully laminated) package may be formed, for example.

Similarly to the process described in connection with FIG. 2C, a position of the laminar structure 201 (or the semiconductor wafer 202 or the die attach wafer 219) may be adjusted in a lateral direction, for example. The lateral direction may be a direction parallel to a main surface of the semiconductor wafer 202 (or to the largest surface of the laminar structure 201 or to the largest surface of the die attach wafer 219), for example.

More details and aspects are mentioned in connection with the embodiments described above or below. The embodiments shown in FIG. 2D may comprise one or more optional additional features corresponding to one or more aspects mentioned in connection with the proposed concept or one or more embodiments described above (e.g. FIGS. 1 to 2C) or below (e.g. FIGS. 2E to 15).

FIG. 2E shows a schematic illustration of a further process 250 for aligning a first laminar structure and a second laminar structure with the semiconductor wafer according to an embodiment.

The process 250 may include aligning the semiconductor wafer 202 (e.g. including an active chip side) and the first laminar structure 201 having the plurality of electrically conductive structures 204 (e.g. metal or copper islands). The process may optionally further include aligning the semiconductor wafer 202 and the second laminar structure 211 having a plurality of second electrically conductive structures 214.

Positions of the laminar structures 201, 211 (and/or the semiconductor wafer 202) may be adjusted in a lateral direction (e.g. to adjust an x-y position of the laminar structure with respect to the semiconductor wafer 202), for example. The lateral direction may be a direction parallel to a main surface of the semiconductor wafer 202 (or to the largest surface of the laminate laminar structure), for example.

The wafers to be aligned (e.g. the semiconductor wafer 202, the first laminar structure 201 and/or the second laminar structure 211) may each include at least one (or e.g. more than one) alignment structure 226, 227 (e.g. recess or holes), to align the wafers with each other. For example, the semiconductor wafer 202, the first laminar structure 201 and the second laminar structure 211 may each include a plurality of recesses or notches 226, 227 arranged at the edge (or circumference) of the respective wafers for positioning or alignment.

The alignment structures 226, 227 of the respective wafers to be aligned (and thus their x-y or lateral positions) may be positioned 254 with respect to each other based on a further positioning structure 222 (e.g. an external positioning structure). For example, the wafers to be aligned may be arranged on the positioning structure 222 (e.g. a steel tool carrier). The positioning structure 222 may include at least one (or e.g. more than one) further alignment structure 223 for engaging with the alignment structures 226, 227 of the respective wafers to be aligned. For example, the further alignment structures 223 may include or may be fixing bolts or locating pins for engaging with the alignment structures 226, 227 of the laminar structures 201, 211 and the semiconductor wafer 202. The further alignment structures 223 may be (temporarily or reversibly) engage, or locked with the alignment structures 226, 227, so that the semiconductor wafer 202, the first laminar structure 201 the second laminar structure 211 may be aligned with respect to each other on the positioning structure 222.

Subsequently, a pressure and/or heat process may be carried out to join the first laminar structure 201 to the first surface 208 of the semiconductor wafer 202 and to join the second laminar structure 211 to the second surface 209 of the semiconductor wafer 202 (simultaneously). For example, the lamination of the semiconductor (Si) wafer 202 may be carried out at the top or front side (e.g. 208) and the bottom or back side (e.g. 209) simultaneously. Thus, fully laminated packages encapsulated on the top side and the bottom side may be obtained at wafer level, for example. The alignment structures 226, 227 may be dimensioned so that a thermal mismatch due to different thermal expansion coefficients of the first laminar structure 201, the semiconductor wafer 202 and a second laminar structure 211 during heating at the joining process may be compensated, for example.

The (glass-based or laminate-based) laminar structure 201, 211 with the vertical electrically conductive structures 204, 214 may be precisely positioned and laminated on the wafer front side and back side. The process may be carried out sequentially or simultaneously. For example, The hardening of the laminate and the connection between metal stack and the chip front and back side may be carried out during the lamination or in a separate (subsequent or downstream) annealing process. Through the deposition of layers on both sides, wafer bow (warpage) from wafer bending due to material stress may be drastically reduced, for example.

Subsequently, a separating (or dicing) process 255 may be carried out to separate the individual dies (each including a semiconductor device structure) of the semiconductor wafer 202 from each other. For example, the separating (or dicing) process may be carried out to singularize individual chip packages (e.g. 224A, 224B) or to create separated chip packages (each including a semiconductor device structure 207 or a semiconductor die).

More details and aspects are mentioned in connection with the embodiments described above or below. The embodiments shown in FIG. 2E may comprise one or more optional additional features corresponding to one or more aspects mentioned in connection with the proposed concept or one or more embodiments described above (e.g. FIGS. 1 to 2D) or below (e.g. FIGS. 2F to 15).

FIG. 2F shows a schematic illustration of a process 260 (e.g. a detailed extract) for forming a semiconductor device 265 according to an embodiment.

By aligning (in 260) the first laminar structure 201 and the semiconductor wafer 202, an electrically conductive structure 204 (e.g. a Cu, Ni or Mo structure) of the first laminar structure 201 may be located adjacent to a semiconductor device structure 207 (or chip) of the semiconductor wafer 202. For example, an electrically conductive structure 204 of the first laminar structure 201 may be located directly adjacent to an electrical contact structure 231 of the semiconductor device structure 207. The electrical contact structure 231 may be located at the first surface 208 of the semiconductor wafer 202. Furthermore, the electrically insulating material 203 (e.g. glass or laminate) of the first laminar structure 201 at the first surface 208 of the semiconductor wafer may be located directly on or adjacent to an edge termination region 232 of the semiconductor device structure 207, for example. Furthermore, the electrically insulating material 203 of the first laminar structure 201 may be located directly on or adjacent to a scribe line region 206.

The edge termination region 232 of the semiconductor device structure 207 may be arranged around (e.g. laterally surround) the active area 233 of the semiconductor device structure 207, for example. At least part of the edge termination region 232 may be formed between the active area 233 of the semiconductor device structure 207 and a scribe line region 206 of the semiconductor device structure 207, for example.

By aligning (in 260) the second laminar structure 211 and the semiconductor wafer 202, an electrically conductive structure 214 (e.g. a Cu, Ni or Mo structure) of the second laminar structure 211 may be located adjacent to the semiconductor device structure 207 (or chip) of the semiconductor wafer 202 on an opposite side to an electrically conductive structure 204 of the first laminar structure 201. For example, an electrically conductive structure 214 of the second laminar structure 211 may be located directly adjacent to an electrical contact structure 234 of the semiconductor device structure 207 at a second surface 209 of the semiconductor wafer 202. Furthermore, the electrically insulating material 213 (e.g. glass or laminate) of the second laminar structure 211 at the second surface 209 of the semiconductor wafer 202 may be located directly on or adjacent to the edge termination region 232, for example. Furthermore, the electrically insulating material of the second laminar structure may be located directly on or adjacent to scribe line region 206 at the second surface of the semiconductor wafer 202, for example.

The electrically conductive structures 204, 214 (or metal structures) may be suitable or may match closely the form (e.g. the shape) and size of the metal contacts 231, 234 (e.g. IGBT emitter, Collector, Gate), on the chip front side (e.g. 208) or on the chip back side (e.g. 209). The chip (or chip contact) surfaces and the laminate metal surfaces may be selected so that through a diffusion solder process, a steady or durable joint or connection may be provided between the metal structures in the laminate and the chip (or chip contact) surfaces.

Glass-based laminar structures 201, 211 may be used, for example. For example, two manufactured glass-metal connection wafers 201, 211 may be wafer bonded with the semiconductor wafer 202 to produce at least one semiconductor device 265. The glass-metal connection wafers 201, 211 may include electrically insulating material (e.g. glass) in which vertical metal structures 204, 214 passing through the electrically insulating material 203, 213, are in the shape and form of the metal contacts 231, 234 on the chip front and back side (e.g. in the form of an IGBT emitter, collector or gate contact structure), for example. These may be exactly or precisely position to be matched to the top and bottom side of a normal semiconductor wafer 202 with a joining process, for example.

Once a wafer bonding sandwich or stack 215 including the semiconductor wafer 202 arranged between the two glass-metal connection wafers 201, 211 is formed, the connection of the glass surface to the semiconductor wafer 202 may take place using a processing procedure under pressure, during the connection of the metal islands of the wafer to the metal pads of the chips through a diffusion solder. A diffusion solder may be deposited on the chip back side (e.g. 209) of the normal wafer 202 and the metal pads 231 of the chip front side (e.g. 208). Alternatively, the diffusion solder material may be deposited on the metal islands 204, 214 of the glass-metal connection wafers 201, 211, or may already be deposited on a side of the metal islands 204, 214 before the manufacture of the glass metal-connection wafer 201, 211. The wafer bond (as a sandwich 215) may be carried out in a single simultaneous joining process. Under pressure and temperature, the connection of the glass surface of the glass-metal connection wafers 201, 211 to the semiconductor wafer 202 and the connection of the metal island areas 204, 214 to the electrical contact structures 231, 234 using a diffusion solder may be carried out simultaneously. Optionally or alternatively, a laser process may be used for the joining of the glass 201, 211 and semiconductor 202, for example.

By carrying out the layer deposition/encapsulation on both sides, wafer bow or wafer bending due to material stresses, may be eliminated or reduced, for example.

The wafer stack 215 shows a part of a wafer area in side view with a diffusion bonded chip, for example. After the manufacturing of a double sided layered wafer structure, a chip individualization process may be carried out in the non-active areas (e.g. the scribe line regions) of the wafer. In this way, a power semiconductor chip may be produced, with metal blocks as cooling bodies on the emitter, collector and gate contact. The encapsulating glass may be used to increase reliability for thinner chips, for example. The semiconductor device produced may be a glass encapsulated power diode with cooling bodies on the emitter, collector and gate contacts, for example.

Although the first laminar structure 201 and the second laminar structure 211 may have been described to be in a wafer form, and the semiconductor wafer 202 has been described to comprise a plurality of chips, it may be understood that optionally or alternatively, a pick and place process may be used. For example, a first laminar structure 201 including electrically conductive structures 204 for a single semiconductor device structure 207 (or chip) may be placed on a first surface 208 of a single (individualized) chip of the semiconductor wafer 202. Similarly, the second laminar structure 211 including electrically conductive structures 214 for the single semiconductor device structure 207 may be placed on a second surface 209 of the chip of the semiconductor wafer 202. The bonding technology may be carried out in parallel for a plurality of sandwich chips in a batch oven, for example.

More details and aspects are mentioned in connection with the embodiments described above or below. The embodiments shown in FIG. 2F may comprise one or more optional additional features corresponding to one or more aspects mentioned in connection with the proposed concept or one or more embodiments described above (e.g. FIGS. 1 to 2E) or below (e.g. FIGS. 2G to 15).

FIG. 2G shows a cross-sectional schematic illustration 270 of an interface between the electrically insulating material 203 of the laminar structure 201 and the semiconductor wafer 202.

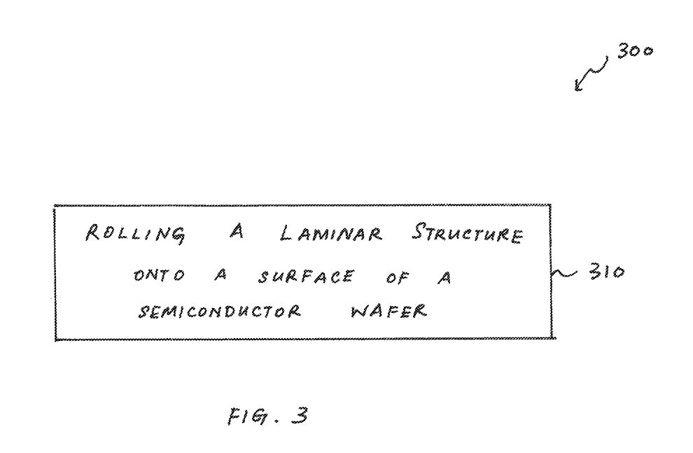

FIG. 2G shows a void-free pressing of glass and silicon, for example. The connection of the glass material of the (glass-metal) laminar structure to the semiconductor wafer 202 may be carried out by applying pressure, during the connection of the metal islands of the wafer to the metal pads of the chips, for example. By heating or pressing the laminar structure 201 to the semiconductor wafer 202, the electrically insulating material 203 (e.g. glass) may be hermetically adhered to the surface of the semiconductor (Si) wafer 202, for example. The glass may fill the voids due to melting of the glass due to the temperature and pressure, for example. More details and aspects are mentioned in connection with the embodiments described above or below. The embodiments shown in FIG. 2G may comprise one or more optional additional features corresponding to one or more aspects mentioned in connection with the proposed concept or one or more embodiments described above (e.g. FIGS. 1 to 2F) or below (e.g. FIGS. 3 to 15).

FIG. 3 shows a flow chart of a method 300 for forming semiconductor devices according to an embodiment.

The method 300 includes rolling 310 a laminar structure onto a surface of a semiconductor wafer comprising a plurality of semiconductor device structures. At least a part of the laminar structure remains to form a part of a semiconductor device to be formed.

Due to the rolling of the laminar structure onto the surface of the semiconductor wafer, flatter semiconductor devices may be produced and very little air is introduced between the laminar structure and the semiconductor wafer, for example. Furthermore, semiconductor devices may be more efficiently produced due to the improved evenness of the semiconductor device package and therefore process outputs for producing semiconductor devices may be increased, for example.

At least part of the laminar structure (e.g. electrically conductive structures of the laminar structure or the electrically insulating material of the laminar structure) may form a part of the semiconductor device to be formed. For example, part of the laminar structure (e.g. at least one electrically conductive structure of the laminar structure or the electrically insulating material of the laminar structure) may form part of a final semiconductor device package including a semiconductor device structure, for example.

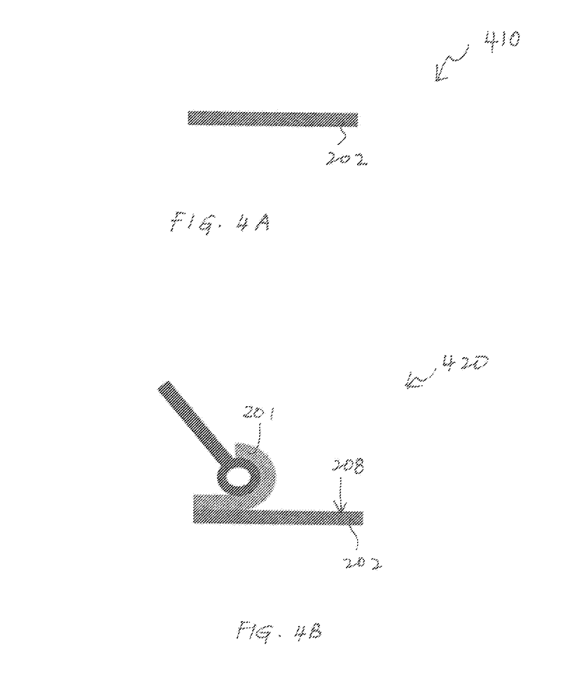

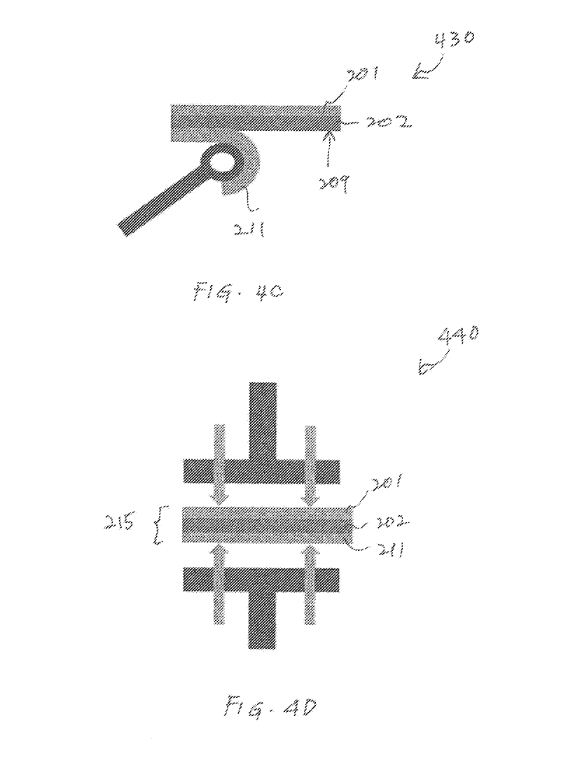

More details and aspects are mentioned in connection with the embodiments described above or below. The embodiments shown in FIG. 3 may comprise one or more optional additional features corresponding to one or more aspects mentioned in connection with the proposed concept or one or more embodiments described above (e.g. FIGS. 1 to 2G) or below (e.g. FIGS. 4A to 15).

FIGS. 4A to 4D show schematic illustrations of a method for forming semiconductor devices according to an embodiment. The method may be similar to the method described in connection with FIG. 3 and FIGS. 1 to 2F.

FIG. 4A shows a schematic illustration 410 of a semiconductor wafer 202 (e.g. a fully processed wafer) after a standard front end process flow.

FIG. 4B shows a schematic illustration 420 of a first laminar structure 201 (laminate with vertical metal structures) being rolled onto a first surface 208 of the semiconductor wafer 202 (e.g. on a wafer front side) as part of the method.

FIG. 4C shows a schematic illustration 430 of a second laminar structure 211 (laminate with vertical metal structures) being rolled onto a second surface 209 of the semiconductor wafer 202 (e.g. on a wafer back side) as part of the method.

The second laminar structure 211 may be rolled onto the second surface 209 of the semiconductor wafer 202 after rolling the first laminar structure 201 onto the first surface 208 of the semiconductor wafer 202. Optionally or alternatively, the first laminar structure 201 and the second laminar structure 211 may be rolled onto the respective surfaces 208, 209 of the semiconductor wafer 202 simultaneously.

The process may further include aligning the first laminar structure 201, the second laminar structure 211 and the semiconductor wafer 202 as described in connection with FIGS. 1 to 2F.

FIG. 4D shows a schematic illustration 440 of a backing (or joining) process for joining the first laminar structure 201 and (optionally) a second laminar structure 211 to the semiconductor wafer 202. For example, heat and/or pressure may be applied to join the first laminar structure 201, the semiconductor wafer 202 and the second laminar structure 211, simultaneous in a single backing process, for example.

Optionally, the joining process for joining the first laminar structure 201 to the semiconductor wafer 202 may be carried out after aligning the first laminar structure 201 to the semiconductor wafer 202, but before aligning and joining the second laminar structure 211 to the semiconductor wafer 202, for example.

After forming the wafer stack 215 including the semiconductor wafer 202, the first laminar structure 201 and/or the second laminar structure 211, a separating (or dicing) process may be carried out to separate the individual dies (each include a semiconductor device structure) of the semiconductor wafer 202 from each other.

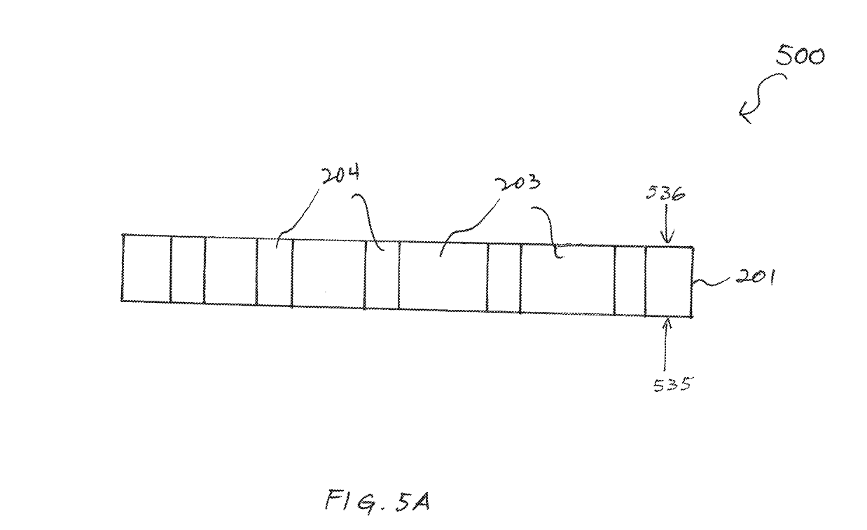

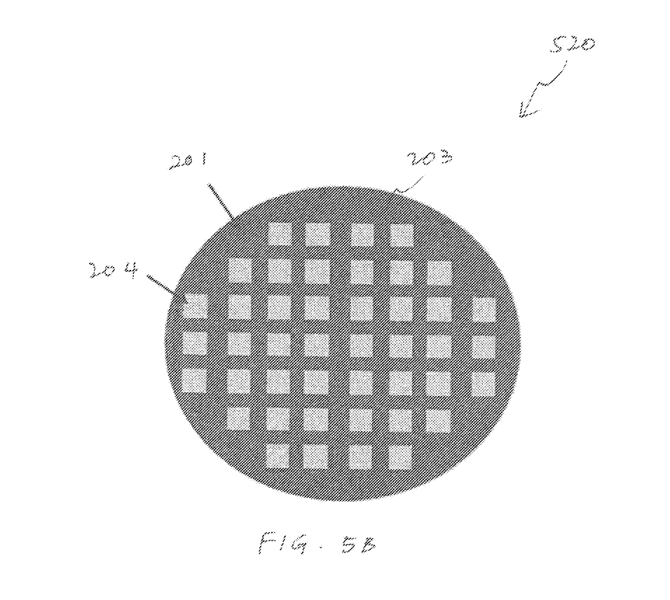

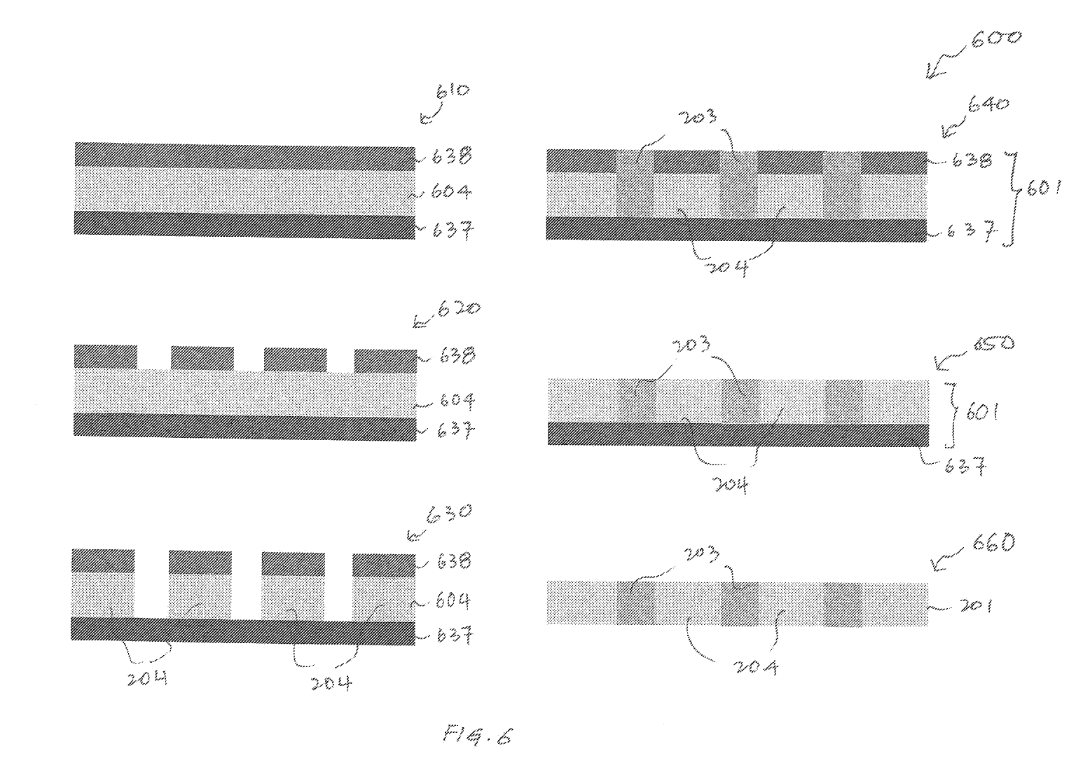

More details and aspects are mentioned in connection with the embodiments described above or below. The embodiments shown in FIGS. 4A to 4D may comprise one or more optional additional features corresponding to one or more aspects mentioned in connection with the proposed concept or one or more embodiments described above (e.g. FIGS. 1 to 3) or below (e.g. FIGS. 5A to 15).

FIG. 5A shows a schematic illustration 500 of a laminar structure 201 according to an embodiment.

The laminar structure 201 includes a plurality of electrically conductive structures 204 and an electrically insulating material 203 arranged between electrically conductive structures 204 of the plurality of electrically conductive structures 204. Each electrically conductive structure 204 of the plurality of electrically conductive structures 204 extends from a first surface 535 of the laminar structure 201 towards a second opposite surface 536 of the laminar structure 201.

Due to the laminar structure 201 comprising electrically conductive structures 204 extending from the first surface 535 of the laminar structure towards the second opposite surface 536 of the laminar structure 201, semiconductor device structures may be more efficiently produced. For example, the process for producing a plurality of semiconductor devices may be simplified as thick metals do not need to be deposited before the electrically insulating material. For example, the electrically conductive structures 204 and the electrically insulating material 203 may be formed or joined to a surface of the semiconductor wafer in a single, simultaneous application process.

The plurality of electrically conductive structures 204 may be exposed at the first surface 535 of the laminar structure and at the second surface 536 of the laminar structure, for example. For example, each electrically conductive structure 204 of the plurality of electrically conductive structures 204 may extend from the first surface 535 of the laminar structure 201 to the second opposite surface 536 of the laminar structure 201. Optionally, the plurality of electrically conductive structures 204 may be exposed at the first surface 535 of the laminar structure 201 and embedded or covered by electrically insulating material 203 at the second surface 536 of the laminar structure 201, for example.

The laminar structure 201 may be similar to the laminar structure described in connection with FIGS. 1 to 4D.

The plurality of electrically conductive structures 204 of the laminar structure 201 may be continuous structures extending from the first surface 535 of the laminar structure 201 towards the second surface 536 of the laminar structure 201. For example, the plurality of electrically conductive structures 204 may be metallic structures (e.g. a metallic pillars or metallic layer stacks). For example, the electrically conductive structures 204 may include copper (Cu), nickel (Ni) or molybdenum (Mo) or alloys of these materials. For example, the electrically conductive structures may be copper structures or molybdenum structures.

Optionally, the plurality of electrically conductive structures 204 may be exposed at the first surface 535 of the laminar structure 201 and at the second surface 536 of the laminar structure 201, for example. For example, each electrically conductive structure 204 of the plurality of electrically conductive structures 204 may extend from the first surface 535 of the laminar structure 201 to the second opposite surface 536 of the laminar structure 201.

Optionally, the plurality of electrically conductive structures 204 may be exposed at only the first surface 535 of the laminar structure. Regions of the plurality of electrically conductive structures 204 towards the second opposite surface 536 of the laminar structure 201 may be covered or surrounded by the electrically insulating material 203 of the laminar structure 201, for example. Processes (e.g. grinding, brushing or polishing) to remove portions of the electrically insulating material 203 covering the plurality of electrically conductive structures 204 at the second surface 536 of the laminar structure 201 may be carried out after placing the laminar structure 201 on the surface of a semiconductor wafer to expose the plurality of electrically conductive structures 204 at the second surface 536 of the laminar structure, for example.

Each electrically conductive structure 204 of the plurality of electrically conductive structures 204 may thus provide an electrically conductive path between the first surface 535 of the laminar structure 201 and the second opposite surface 536 of the laminar structure 201, for example. For example, each electrically conductive structure 204 may be suitable for carrying a current signal or voltage signal from the first surface 535 of the laminar structure 201 towards the second opposite surface 536 of the laminar structure 201, or between the first surface 535 of the laminar structure 201 and the second opposite surface 536 of the laminar structure 201.

The electrically conductive structures 204 may have an average thickness of between 10 μm and 500 μm (or e.g. between 50 μm and 350 μm or e.g. between 50 μm and 150 μm), for example. The average thickness of the electrically conductive structures 204 may be an average height of the electrically conductive structures 204 measured in a direction between the first surface 535 of the laminar structure 201 and the second surface 536 of the laminar structure 201, for example. The average thickness of the electrically conductive structures 204 may be a thickness of the electrically conductive structures 204 averaged over a region of interest of the laminar structure 201, for example.

An average thickness of the electrically conductive structures 201 and an average thickness of the electrically insulating material 203 may be similar (or the same). For example, a deviation or variation of the average thickness of the electrically conductive structures 204 and the average thickness of the electrically insulating material 203 may be less than 10%,

An arrangement (or layout) of the plurality of electrically conductive structures 204 in the laminar structure 201 may correspond to an arrangement of a plurality of electrical contact structures of a plurality of semiconductor device structures at a first surface of the semiconductor wafer, for example. For example, a maximum lateral dimension (e.g. length, or diagonal length) of an (or each) electrically conductive structure 204 of the plurality of electrically conductive structures 204 may be equal to or be proportional to a maximum lateral dimension of its corresponding electrical contact structure at the first surface of the semiconductor wafer. Additionally or optionally, a maximum lateral dimension (e.g. length, or diagonal length) of an (or each) electrically conductive structure 204 of the plurality of electrically conductive structures 204 may be larger than a maximum lateral dimension of its corresponding electrical contact structure at the first surface of the semiconductor wafer by a scaling constant, for example. For example, the scaling constant may lie between 1% and 5%, for example. For example, a maximum lateral dimension of an (or each) electrically conductive structure 204 of the plurality of electrically conductive structures may be larger than a maximum lateral dimension of its corresponding electrical contact structure at the first surface of the semiconductor wafer by less than 5 μm, for example. The plurality of electrically conductive structures 204 may have a maximal lateral dimension of more than 10 μm (or e.g. more than 15 μm or e.g. more than 20 μm), for example.

Additionally or optionally, a spacing or distance between electrically conductive structures 204 in the laminar structure 201 may be equal to or proportional to a spacing or distance a plurality of electrical contact structures of the plurality of semiconductor device structures at the first surface of the semiconductor wafer, for example. For example, a distance between neighboring electrically conductive structures 204 in the laminar structure may be less than 1 μm (or e.g. less than 2 μm or e.g. less than 10 μm).

The laminar structure 201 may be a thin plate, a sheet or a layer. A first surface 535 or second surface 536 of the laminar structure may be a substantially even plane. The laminar structure may have an average lateral dimension (e.g. an average diameter or average length) of between 50 mm and 450 mm, for example. Optionally, the laminar structure may have an average lateral dimension larger than 450 mm, (or e.g. larger than 1 m, or larger than several meters, or larger than several tens of meters).

The laminar structure 201 may have a maximal thickness of between 10 μm and 500 μm (or e.g. between 50 μm and 350 μm or e.g. between 50 μm and 150 μm), for example. The maximal thickness of the laminar structure 201 may be a largest height of the laminar structure measured in a direction between the first (lateral) surface of the laminar structure and the second opposite (lateral) surface of the laminar structure.

The laminar structure 201 may be in the form of a wafer. The laminar structure 201 may be a substantially flat or even structure. For example, an average thickness of the electrically conductive structures 204 and an average thickness of the electrically insulating material 203 may be similar (or the same). For example, a deviation or variation of the average thickness of the electrically conductive structures 204 and the average thickness of the electrically insulating material 203 may be less than 10%, for example. Thus, a lateral surface of the laminar structure 201 may have a topography variation of less than 10 μm over an area span of a semiconductor wafer (e.g. over an area span equal to or larger than a 200 mm diameter semiconductor wafer), for example. For example, a lateral surface of the laminar structure 201 may have a topography variation of less than 2 μm over an area span of a semiconductor device or semiconductor die (e.g. over an area span equal to or larger than a 2 mm×2 mm semiconductor die).

The laminar structure 201 may include electrically insulating material 203 arranged between the plurality of electrically conductive structures 204. For example, the electrically insulating material 203 may be formed in regions between neighboring electrically conductive structures 204 of the plurality of electrically conductive structures, for example. For example, the electrically insulating material 203 may be located (directly) on sidewalls of the electrically conductive structures 204. For example, the electrically insulating material may laterally surround the electrically conductive structures.

The electrically insulating material 203 may have an average thickness of between 10 μm and 500 μm (or e.g. between 50 μm and 350 μm or e.g. between 50 μm and 150 μm), for example. The average thickness of the electrically insulating material 203 may be an average thickness of the electrically insulating material 203 measured in a direction between the first surface 535 of the laminar structure 201 and the second surface 536 of the laminar structure 201, for example. The average thickness of the electrically insulating material 203 may be a thickness of the electrically insulating material 203 averaged over a region of interest of the laminar structure, for example.

The electrically insulating material 203 of the laminar structure may include or may be a laminate material, for example. For example, the laminate material may be a polymer based laminate. For example, the polymer based laminate may include polyimide, polyacrylate or epoxy resin, or a mixture of these. Additionally or optionally, the electrically insulating material 203 may include a laminate material and thermally conductive filler particles, for example. The thermally conductive filler particles may be embedded in the laminate material, for example. The thermally conductive filler particles may include or may be aluminum oxide particles, boron nitride particles, alumina nitride particles or ceramic particles. The thermally conductive filler particles may be at least 90% of the volume of the electrically insulating material, for example. For example a ratio of thermally conductive filler particles to laminate material may be at least 90:10, for example.

Alternatively, the electrically insulating material 203 of the laminar structure may include or may be glass. For example, the glass may include or may be a low melting glass alloy (e.g. with melting points between 250 and 500° C.). Additionally or optionally, the electrically insulating glass may include thermally conductive filler particles and/or filler particles with low thermal expansion, for example.

More details and aspects are mentioned in connection with the embodiments described above or below. The embodiments shown in FIG. 5A may comprise one or more optional additional features corresponding to one or more aspects mentioned in connection with the proposed concept or one or more embodiments described above (e.g. FIGS. 1 to 4D) or below (e.g. FIGS. 5B to 15).

FIG. 5B shows a schematic illustration 520 of a top view of the laminar structure 201 according to an embodiment.

The laminar structure 201 may be a polymer laminate in wafer form and size, which may include (or consist of) an electrically isolating (and thermally conductive) filled polyimide or epoxy resin, for example. Alternatively, the laminar structure 201 may be a glass-based laminar structure in wafer form and size. The vertical continuous metal structures 204 may be inserted in the laminate or glass, for example. The vertical continuous metal structures 204 (e.g. metal islands) may be mechanically flexible and rollable like a laminate sheet, for example. The laminar structure 201 may thus be a flexible or rollable (can be rolled) laminar structure, for example.

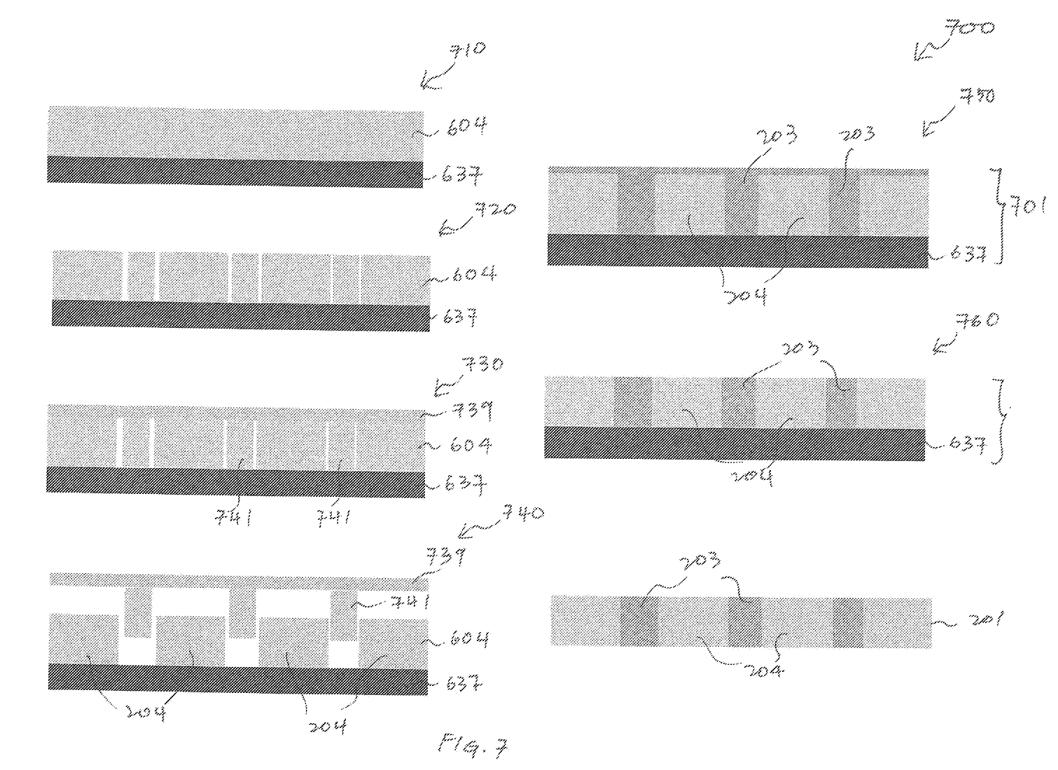

More details and aspects are mentioned in connection with the embodiments described above or below. The embodiments shown in FIG. 5B may comprise one or more optional additional features corresponding to one or more aspects mentioned in connection with the proposed concept or one or more embodiments described above (e.g. FIGS. 1 to 5A) or below (e.g. FIGS. 6 to 15).

FIG. 6 shows a schematic illustration of a method 600 for forming a laminar structure according to an embodiment. The method 600 may be used for the production of a laminate with copper islands, for example.

The method 600 may include forming 610 a layer of electrically conductive material 604 over or on a surface of a temporary carrier 637 (e.g. a substrate). The temporary carrier 637 may be a semiconductor substrate, for example. The electrically conductive material 604 may include a metal (e.g. Cu, Ni or Mo). The electrically conductive material formed 604 may be the same material as electrically conductive structures to be formed, for example.

The layer of electrically conductive material 604 may have a thickness ranging from about 20 μm to about 800 μm, for example.

The method 600 may further include (subsequently) forming a mask layer 638 on the layer of electrically conductive material 604. The mask layer may 638 include a photoresist material (e.g. a layer of photoresist), which may cover or be formed directly on the electrically conductive material 604.

The method 600 may further include (subsequently) structuring 620 the mask layer 638 to expose surface regions of the electrically conductive material 604. Structuring the mask layer 638 may be carried out using photolithography to remove at least one portion of the mask layer 638 to expose a surface region of the layer of electrically conductive material 604. The mask layer 638 may be structured based on a pattern or based on an arrangement (or layout) of electrical contact structures of semiconductor structures in a semiconductor wafer so that the arrangement of the structured mask layer on the electrically conductive material is based on the arrangement of electrical contact structures.

The method 600 may further include (subsequently) removing 630 exposed regions of the electrically conductive material 604 (from the temporary carrier 637). The removal of the electrically conductive material 604 may be carried by etching, sawing and/or stamping, for example. Electrically conductive structures 204 (e.g. vertical metal structures) may remain on the temporary carrier.

The method 600 may further include (subsequently) incorporating 640 or depositing electrically insulating material 203 (e.g. filled resin) in regions between the electrically conductive structures 204 remaining on the temporary carrier 637. The electrically insulating material 203 may be incorporated by filling regions between neighboring electrically conductive structures 204 to form a laminar stack, for example. The electrically insulating material 203 may be deposited by spin-on processes, lamination processes, or dispensing processes, for example. The electrically insulating material 203 may include a resin (e.g. an epoxy resin), or a polymer-based laminate material, or a mixture of these, for example. The method 600 may further include curing the electrically insulating material 203, for example.

The method boo may further include (subsequently) grinding or etching 650 the laminar arrangement 601 (from a surface of the laminar arrangement 601 opposite to the temporary carrier 637) to remove the mask layer 638 and to reduce the thickness of the laminar arrangement 601 to a required thickness (and/or smoothness). The final thickness of the thinned laminar arrangement 601 (not including the thickness of the temporary carrier 637) may lie between 10 μm and 500 μm (or e.g. between 50 μm and 350 μm or e.g. between 50 μm and 150 μm), for example.

The method 600 may include (subsequently) removing 660 the temporary carrier from the laminar stack to obtain the laminar structure 201.

The method 600 may be used to produce a laminate with metal (e.g. copper) islands, for example. The method 600 may be used at wafer level for high dimension accuracy and wafer shape or for a panel format. For example, the method 600 may be used to produce a laminar structure in the shape or form of a semiconductor wafer 202 or in a panel (e.g. quadrangular or rectangular format). A top view of the laminar structure 201 (e.g. in wafer form) may be similar to that shown in FIG. 5B, for example.

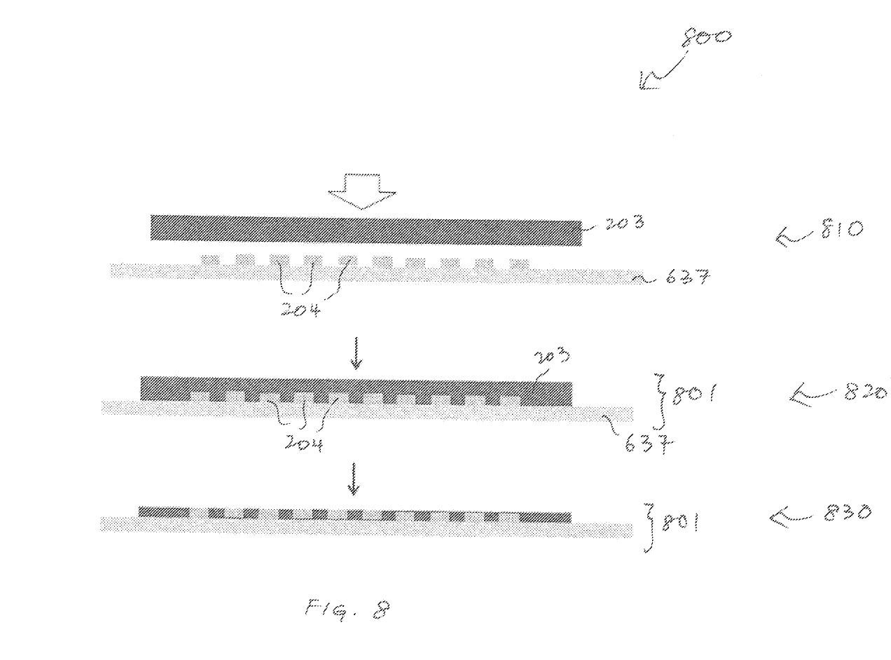

More details and aspects are mentioned in connection with the embodiments described above or below. The embodiments shown in FIG. 6 may comprise one or more optional additional features corresponding to one or more aspects mentioned in connection with the proposed concept or one or more embodiments described above (e.g. FIGS. 1 to 5B) or below (e.g. FIGS. 7 to 15).

FIG. 7 shows a schematic illustration of a further method 700 for forming a laminar structure according to an embodiment. For example, the method 700 may be used for the production of a laminate with copper islands, for example.

The method 700 may include forming 710 a layer of electrically conductive material 604 over or on a surface of a temporary carrier 637 (e.g. a substrate). The process for forming the layer of electrically conductive material 604 may be similar to the process described in connection with FIG. 6

The method 700 may further include (subsequently) stamping regions 720 of the layer of electrically conductive material 604. The stamping may be carried out to create voids or trenches in the layer of electrically conductive material 604 so that portions of the layer of electrically conductive material 604 may be removed. The stamping of selected regions of the layer of electrically conductive material 604 may be carried based on a pattern or based on an arrangement (or layout) of electrical contact structures on a surface of a semiconductor wafer, for example.

The method 700 may further include arranging 730 an adhesive structure 739 over the layer of electrically conductive material 604 to remove unwanted regions 741 of electrically conductive material from the layer of electrically conductive material 604 and the temporary carrier 637.

The method 700 may further include removing 740 the unwanted regions 741 of electrically conductive material from the layer of electrically conductive material 604 and the temporary carrier 637. Portions of the electrically conductive material 604 may be removed so that electrically conductive structures 204 (e.g. vertical metal structures) remaining on the temporary carrier 637 may correspond to an arrangement of electrical contact structures on the surface of a semiconductor wafer, for example. The unwanted regions 741 of electrically conductive material may be removed by attaching them to the adhesive structure 739 or an adhesive sheet so that the portions of the electrically conductive material 604 are detached from the surface of the temporary carrier 637.

The method 700 may further include (subsequently) incorporating 750 or depositing electrically insulating material 203 in regions between the electrically conductive structures 204 remaining on the temporary carrier to form a (laminate) laminar arrangement 701. The electrically insulating material 203 may be incorporated by filling regions between neighboring electrically conductive structures 204, for example. The electrically insulating material 203 may be deposited by liquid application processes, lamination processes, or casting processes, for example. The electrically insulating material 203 may include a resin (e.g. an epoxy resin), polymer-based laminate material or glass, for example.

The method 700 may further include (subsequently) grinding or brushing 760 the laminar arrangement (from a surface of the laminar arrangement opposite to the temporary carrier) to reduce the thickness of the laminar arrangement to a required thickness. The final thickness of the thinned laminar arrangement 701 (not including the thickness of the temporary carrier 637) may lie between 10 μm and 500 μm (or e.g. between 50 μm and 350 μm or e.g. between 50 μm and 150 μm), for example.

The method 700 may include (subsequently) removing 770 or delaminating the temporary carrier 637 from the laminar arrangement 701 to obtain a laminar structure 201 to be placed on a surface of a semiconductor wafer, for example.

The method 700 may be used for the production of a laminate with metal (e.g. copper) islands, for example. The method 700 may be for high volume production, and may be subsequently sized according to wafer dimensions. While accuracy may be limited, the method 700 may be free from wet processes like etching, for example.

A top view of the laminar structure 201 (e.g. in wafer form) may be similar to that shown in FIG. 5B, for example.

More details and aspects are mentioned in connection with the embodiments described above or below. The embodiments shown in FIG. 7 may comprise one or more optional additional features corresponding to one or more aspects mentioned in connection with the proposed concept or one or more embodiments described above (e.g. FIGS. 1 to 6) or below (e.g. FIGS. 8 to 15).

FIG. 8 shows a further method 800 for forming a laminar structure (e.g. a glass laminar structure) according to an embodiment. For example, FIG. 8 shows a cross-sectional view of the production of a glass-metal wafer.

The method 800 may include forming a plurality of electrically conductive structures 204 on a surface of a temporary carrier 637 (e.g. a substrate). The plurality of electrically conductive structures 204 may have a layout corresponding to a layout of electrical contact structures on a surface of a semiconductor wafer. Similar to the processes described in connection with FIGS. 6 and 7, the plurality of electrically conductive structures 204 may be formed by forming a layer of electrically conductive material over or on a surface of a temporary carrier (e.g. a substrate) and (subsequently) removing regions of the electrically conductive material from the temporary carrier.

The method 800 may include (subsequently) incorporating 810 or depositing electrically insulating material 203 (e.g. glass or powder, or glass powder) in regions between the electrically conductive structures 204 arranged on the temporary carrier 637 to form a laminar arrangement 801.

The method 800 may further include melting 820 the glass (or glass powder) by an application of heat (e.g. a high temperature) and pressure so that the electrically insulating material fills the gaps or regions between neighboring electrically conductive structures, for example.

The method 800 may further include (subsequently) grinding 830 the laminar arrangement 801 (from a surface of the laminar arrangement 801 opposite to the temporary carrier 637) to expose the electrically conductive structures 204 and to reduce the thickness of the laminar arrangement 801 to a required thickness. The final thickness of the thinned laminar arrangement 801 (not including the temporary carrier 637) may lie between 10 μm and 500 μm (or e.g. between 50 μm and 350 μm or e.g. between 50 μm and 150 μm), for example.

The method 800 may further include (subsequently) removing or the temporary carrier 637 from the laminar arrangement 801 to obtain a laminar structure to be placed on a semiconductor wafer, for example.

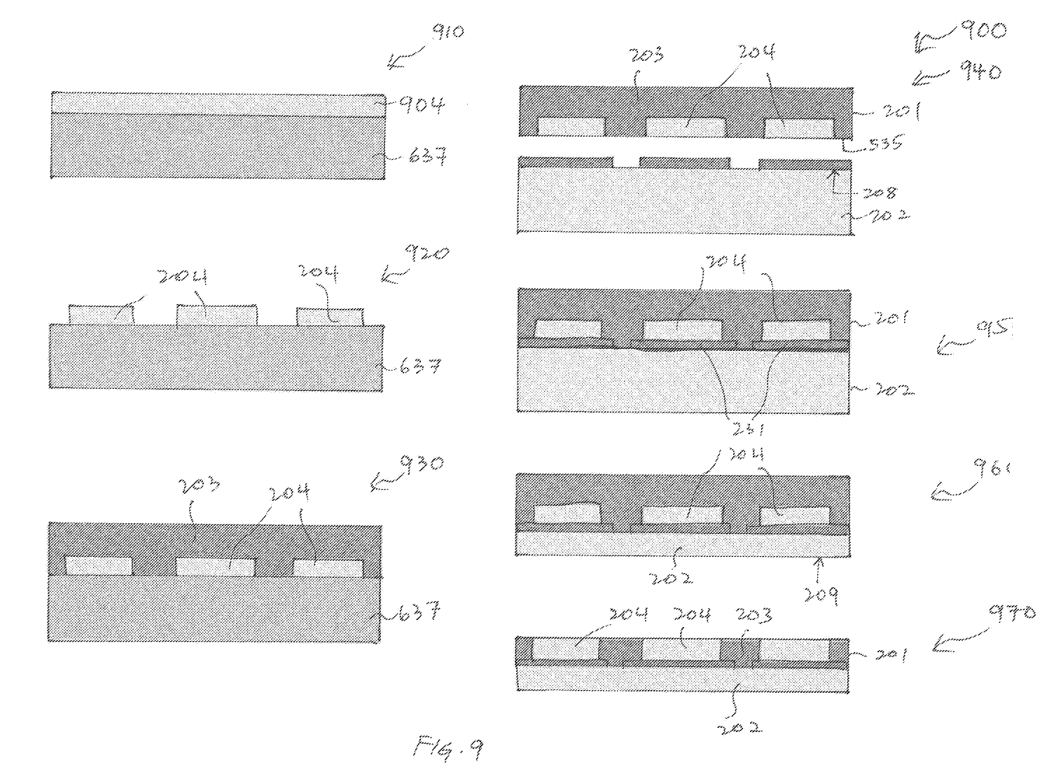

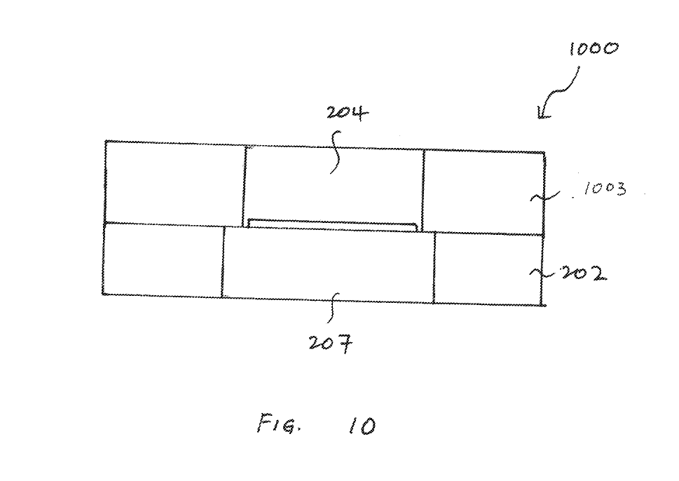

More details and aspects are mentioned in connection with the embodiments described above or below. The embodiments shown in FIG. 8 may comprise one or more optional additional features corresponding to one or more aspects mentioned in connection with the proposed concept or one or more embodiments described above (e.g. FIGS. 1 to 7) or below (e.g. FIGS. 9 to 15).

FIG. 9 shows a method 900 for forming semiconductor devices according to an embodiment. The method may include forming (or manufacturing) a glass wafer with metal islands (Cu, Ni or Mo) to form a laminar structure, e.g. a glass-metal wafer.

The method 900 may include arranging 910 a metal foil 904 on a surface of a temporary carrier 637.

The method 900 may further include structuring 920 the metal foil 904 to form a plurality of electrically conductive structures 204 on the temporary carrier 637.

The method 900 may further include pressing 930 an electrically insulating material 203 (e.g. glass) to the surface of the temporary carrier 637. The electrically insulating material 203 may be arranged between neighboring electrically conductive structures 204, or may encapsulate the electrically conductive structures.

The method 900 may further include removing the temporary carrier 637 to obtain a laminar structure 201 comprising the electrically insulating material 203 and the electrically conductive structures 204, and placing 940 the laminar structure 201 onto a first surface 208 of a semiconductor wafer 202. The electrically conductive structures 204 may be exposed at the first surface 535 of the laminar structure, for example.

The method 900 may further include subsequently joining 950 the laminar structure 201 to the semiconductor wafer 202. Through a heat press assembly process, the laminar structure 201 may be bonded to a semiconductor wafer 202. Diffusion soldering may be carried out to join the laminar structure 201 (e.g. a metal-glass wafer or a metal-laminate wafer) with the metallized product wafer (e.g. the semiconductor wafer 202 comprising the plurality of semiconductor device structures), for example. This may produce a connected wafer stack system with embedded silicon and electrically conductive vias 204, for example. Optionally, a diffusion solder material may be applied on the front side 208 of chips of the semiconductor wafer 202 before the diffusion soldering process. Through the diffusion solder material, a solder joint may be formed between the metal islands 204 of the glass wafer and electrical contact structures 231 formed at the front side 208 of the semiconductor wafer, for example.

Furthermore, a connection may be formed between the glass surface and surface regions of the semiconductor wafer 202 that are not connected with the metal islands 204. Through the permanent connection and carriage arrangement, very thin chips having a thickness of less than 5 μm may be formed.

The method 900 may further include 960 thinning (or grinding) the semiconductor wafer 202 from a second surface (e.g. a back side) of the semiconductor wafer 202 so that a target or desired thickness of the semiconductor wafer 202 is achieved. The final thickness of the thinned semiconductor wafer 202 may be less than 200 μm or e.g. less than 50 μm or e.g. less than 10 μm (or e.g. between 20 μm and 30 μm), for example. The method 900 may be used to form very thin semiconductor layers, in which the semiconductor material (or wafer) 202 may be ground or thinned with another method after the glass pressing, which may not be possible without mechanical stabilization by the glass wafer, for example.

The method 900 may further include (optionally) grinding or thinning 970 the laminar structure (from a surface of the laminar structure opposite to the temporary carrier) so that the surface regions of the electrically conductive structures are exposed at the second surface of the laminar structure. For example, the vias on the glass side may be exposed or freed. For example, the grinding or thinning of the protruding glass may expose metal islands of the glass wafers. The laminar structure may be grinded until a total target thickness of the semiconductor device is obtained, for example. The final target thickness of the semiconductor device package may be less than 300 μm, or e.g. less than 100 μm, or e.g. less than 50 μm, for example.

The method 900 may be used to form thick metal stacks 204 on the front side (e.g. 208) or back side (e.g. 209) of a chip at wafer level, through a special glass wafer 201 with metal islands 204 (e.g. a glass-metal connection system) by a glass pressing process. The glass-metal-connect wafer 201 may have an electrically isolating glass matrix 203 and metal structures 204, which may be fitted to the shape and size of respective chip metallizations 231 234 (e.g. front side and/or back side contact pads). The electrically insulating material 203 and the metal areas 204 of the laminar structure 201 (e.g. the laminate) may form a plane and may have the same thickness (e.g. between 10 and 200 μm), for example.

Through wafer-level-chip-scale-packaging (WLCSP) very thin chips in electronic components may be processed which may be used for power semiconductor applications. A thinner chip from a few μm to 10 μm may be desired, which may starkly reduce static and dynamic losses due to the small thicknesses. The smaller chip thickness may be a key driver to reduce the losses and may be a reason for chip shrinkage and cost reduction, for example.

The method 900 may avoid challenges due to the use of polymer encapsulations or connection materials, which may reduce the reliability through increased humidity and ion transport, e.g. (through the use of polyimide). In addition, material shrinkage due to the hardening of polymers, (which may lead to bending or warpage of the thin wafers, stress on the boundary or edge regions and delamination) may be avoided. Differences between the thermal expansion coefficient of the polymer connection layers and the semiconductor material may lead to more thermo-mechanical stress in the boundary or edge regions from heating or cooling. The method 900 may provide sufficient mechanical stability in thin wafers or chips in the front end with reversible carrier techniques. The reversible carriers may be used to allow access to the respective surfaces which are not free or exposed, for example.

The method 900 may be used to process extremely thin semiconductor wafers using a carrier. The processes may be carried once the wafer is thinned. The temporary carrier 637 may be a mechanically rigid material. Polymer materials result in a large limitation on the temperature of following processes. By switching from back side to a front side processes, a carrier may be used to carry the thin wafers (glass carrier light concept) to provide a continuous support, for example. For example, wafer warpage (e.g. stress on the wafer) and reduction in reliability for subsequent processes during the cooling process due to the different thermal expansion coefficients (e.g. between plastics and the semiconductor material) may be avoided. Warpage and stress may be reduced even with high performance plastics such as (e.g. polyimide, BCB).

For WLCSP (e.g. in shell case type variations), glass may be used as an isolation layer, and may be formed on the silicon using an adhesive. Method 900 may avoid additional curing process of the adhesive and the drilling of production holes in the glass, so that the vias may be filled.

The method 900 may lead to the manufacture or production of thinner chips with cooling bodies on the electrical contacts, and a hermetic isolation. This may lead to better performance and reliability. The method 900 may increase of the cooling performance of the chip or semiconductor device through the possibility of thickness variation of the metal blocks (e.g. between 10 μm to 15 μmm). The method 900 may increase the process reliability through the reduction of wafer bending by encapsulating the chip top (front) and bottom (back) side simultaneously. The method 900 may simplify the chip individualization process by avoiding slicing through thick or hard metal in connection with the soft polymer material, for example. The method 900 may provide a permanent carrier concept for mean process temperatures below the glass transition temperature (Tg) of the glass, for example. Rigid support may be provided for the semiconductor substrate for processes following thinning of the semiconductor substrate, for example.

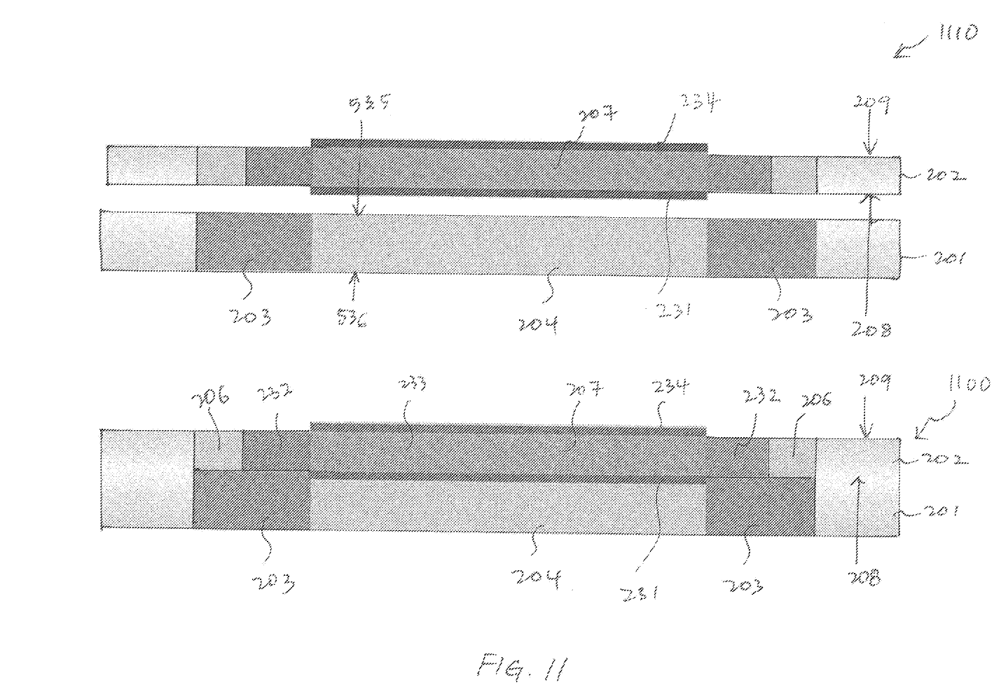

More details and aspects are mentioned in connection with the embodiments described above or below. The embodiments shown in FIG. 9 may comprise one or more optional additional features corresponding to one or more aspects mentioned in connection with the proposed concept or one or more embodiments described above (e.g. FIGS. 1 to 8) or below (e.g. FIGS. 10 to 15).

FIG. 10 shows a schematic illustration of a semiconductor device 1000 according to an embodiment.

The semiconductor device 1000 comprises a semiconductor device structure 207 formed in a semiconductor substrate 202. The semiconductor device 1000 further comprises a polymer-based or glass-based electrically insulating laminar structure 1003 laterally surrounding at least one electrically conductive structure 204.

Due to the electrically insulating laminar structure 203 laterally surrounding the electrically conductive structure 204, a flatter or smaller semiconductor device package may be obtained. Furthermore, the semiconductor device 1000 may be more easily produced, for example.

The semiconductor device structure of the semiconductor device may include a metal oxide semiconductor field effect transistor (MOSFET) structure, a bipolar junction transistor (BJT) structure, an insulated gate bipolar transistor (IGBT) structure, a diode structure or a thyristor structure, for example.

The electrically insulating laminar structure 1003 may be similar to the electrically insulating material 203 described in connection with FIGS. 1 to 9, for example. The electrically insulating laminar structure 1003 may be a polymer based laminate, for example. For example, the polymer based laminate may include polyimide or epoxy resin. Additionally or optionally, the electrically insulating laminar structure 1003 may include a laminate material and thermally conductive filler particles, for example. The thermally conductive filler particles may include or may be aluminum oxide particles or ceramic particles. The thermally conductive filler particles may be at least 90% of the volume of the electrically insulating laminar structure, for example. For example a ratio of thermally conductive filler particles to laminate material may be at least 90:10, for example.

The electrically insulating laminar structure 1003 may be arranged (directly) adjacent to or may be arranged on an edge termination region and a scribed line region of the semiconductor device structure 207, for example.

The electrically insulating laminar structure 1003 and the at least one electrically conductive structure 204 may be located adjacent to the semiconductor device structure 207 on a first surface of the semiconductor substrate, for example.

The electrically conductive structure 204 may be a metallic structure, for example. For example, the electrically conductive structure 204 may include copper (Cu), nickel (Ni) or molybdenum (Mo) or an alloy of these materials.

A first surface of the electrically conductive structure 204 may be arranged directly adjacent to an electrical contact structure of the semiconductor device structure, for example. A second opposite surface of the electrically conductive structure may be connected to a wire bond, for example. The wire bond may be joined (e.g. solder joined) to the electrically conductive structure 204, for example. Each electrically conductive structure 204 of the semiconductor device 1000 may be connected to its own wire bond, for example. The wire bond may be electrically connected with an external lead frame or printed circuit board, for example.

Alternatively or optionally, solder material may be arranged on a second opposite surface of the electrically conductive structure 204, so that the second opposite surface of the electrically conductive structure 204 may be soldered to a printed circuit board or an external lead frame structure, for example.

The semiconductor device including the laminar structure may have a topography variation of less than 25 μm over an area span of a semiconductor wafer (e.g. over an area span equal to or larger than a 200 mm diameter semiconductor wafer), for example. For example, the semiconductor device including the laminar structure may have a topography variation of less than 10 μm over an area span of a semiconductor device or semiconductor die (e.g. over an area span equal to or larger than a 2 mm×2 mm semiconductor die).

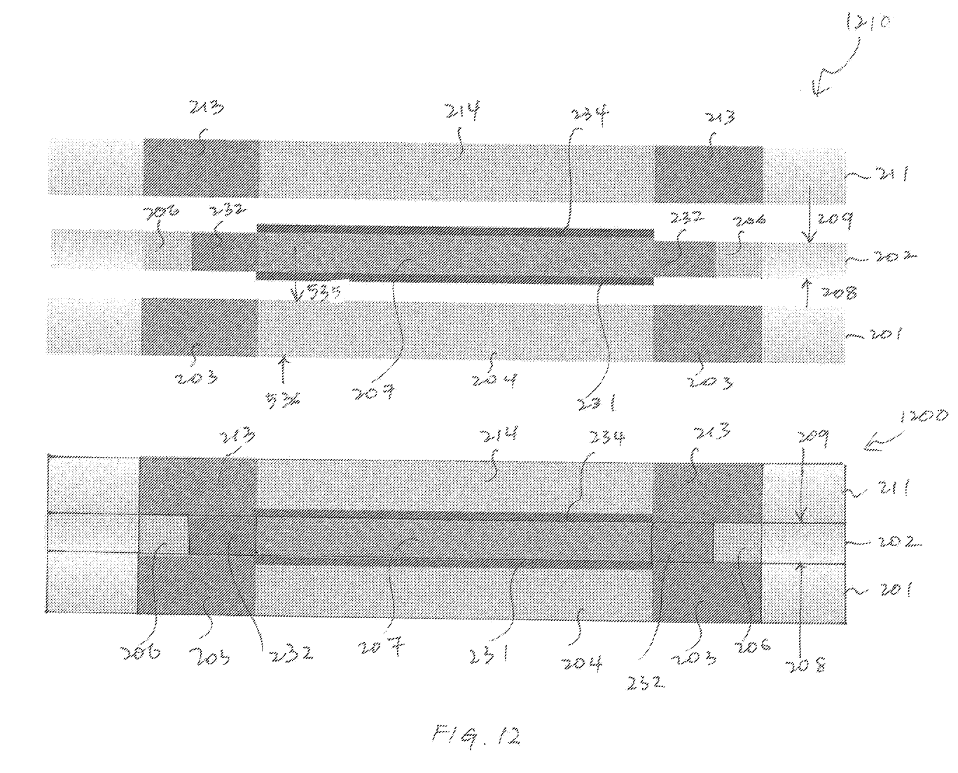

More details and aspects are mentioned in connection with the embodiments described above or below. The embodiments shown in FIG. 10 may comprise one or more optional additional features corresponding to one or more aspects mentioned in connection with the proposed concept or one or more embodiments described above (e.g. FIGS. 1 to 9) or below (e.g. FIGS. 11 to 15).

FIG. 11 shows a schematic illustration of a semiconductor device 1100 according to an embodiment.

The semiconductor device 1100 may include a semiconductor substrate 202 including a semiconductor substrate material (e.g. a semiconductor substrate wafer), for example. For example, the semiconductor substrate material may be a silicon-based semiconductor substrate material, a silicon carbide-based semiconductor substrate material, a gallium arsenide-based semiconductor substrate material or a gallium nitride-based semiconductor substrate material, for example.

The semiconductor substrate 202 may include a semiconductor device structure 207. For example, the semiconductor device structure 207 may include a metal oxide semiconductor field effect transistor (MOSFET) structure, a bipolar junction transistor (BJT) structure, an insulated gate bipolar transistor (IGBT) structure, a diode structure or a thyristor structure, for example.

The semiconductor device 1100 may include at least one electrical contact structures 231 (chip metallization) located on the first surface 208 of the semiconductor substrate 202 and one or more further electrical contact structures 234 located on the second surface 209 of the semiconductor substrate 202. The at least one electrical contact structure 231, 234 may be electrically connected (directly or optionally via one or more interconnects or intermediate layers) to the electrically conductive active elements (e.g. source/emitter regions, drain/collector regions or gate/base regions) formed in the active area of the semiconductor device structure for example.

The semiconductor device 1100 may include one laminar structure 201 arranged or placed (in 1110) on a first surface 208 of the semiconductor substrate 202. The laminar structure 201 may be arranged on the top (front) side or the bottom (back) side of the semiconductor wafer, for example. The second laminar structure may be omitted, for example. The laminar structure 201 may include electrically insulating material 203 (electrically isolating material) laterally surrounding at least one electrically conductive structure of the laminate structure, for example. The electrically insulating material 203 may include laminate or glass, for example.

The electrically conductive structure 204 (metal stack integrated in the glass or laminate structure) may be located adjacent to the semiconductor device structure 207, for example. The electrically conductive structure 204 may provide an electrically conductive path between a first surface 535 of the laminar structure 201 and a second opposite surface 536 of the laminar structure 201, for example.

The electrically conductive structure 204 of the laminar structure 201 may be arranged adjacent to a first electrical contact structure 231 of the semiconductor device structure 207. The first electrical contact structure 231 may be in electrical connection with a source region or an emitter region of a transistor structure, for example. For example, in a diode structure, the first electrical contact structure may be electrically connected to a first doping region (of a first conductivity type, e.g. a p-type doping region) or anode region of the diode structure.

The electrically insulating material 203 of the laminar structure 201 may be arranged on or adjacent to an edge termination region 232 of the semiconductor device structure 207, for example. The edge termination region 232 of the semiconductor device structure 207 may be arranged around the active area 233 of the semiconductor device structure 207, for example. For example, the edge termination region 232 of the semiconductor device structure 207 may laterally surround the active area 233 of the semiconductor device structure 207, for example. At least part of the edge termination region 232 may be formed between the active area 233 of the semiconductor device structure 207 and a scribe line region 206 of the semiconductor device structure 207, for example. The electrically insulating material 203 of the laminar structure 201 may be arranged on or adjacent to the scribe line region 206 of the semiconductor substrate 202, for example.

The laminar structure 201 may be joined or soldered (e.g. diffusion soldered) to the semiconductor substrate comprising the semiconductor device structure 207 to form the semiconductor device 1100.

The second surface 536 of the first laminar structure 204 may be arranged adjacent to an external printed circuit board or external lead frame structure, for example. For example, a wire bond or solder material may be formed on the second surface of the electrically conductive structures 204 so that the electrically conductive structures 204 may be electrically connected with an external lead frame or printed circuit board, for example.

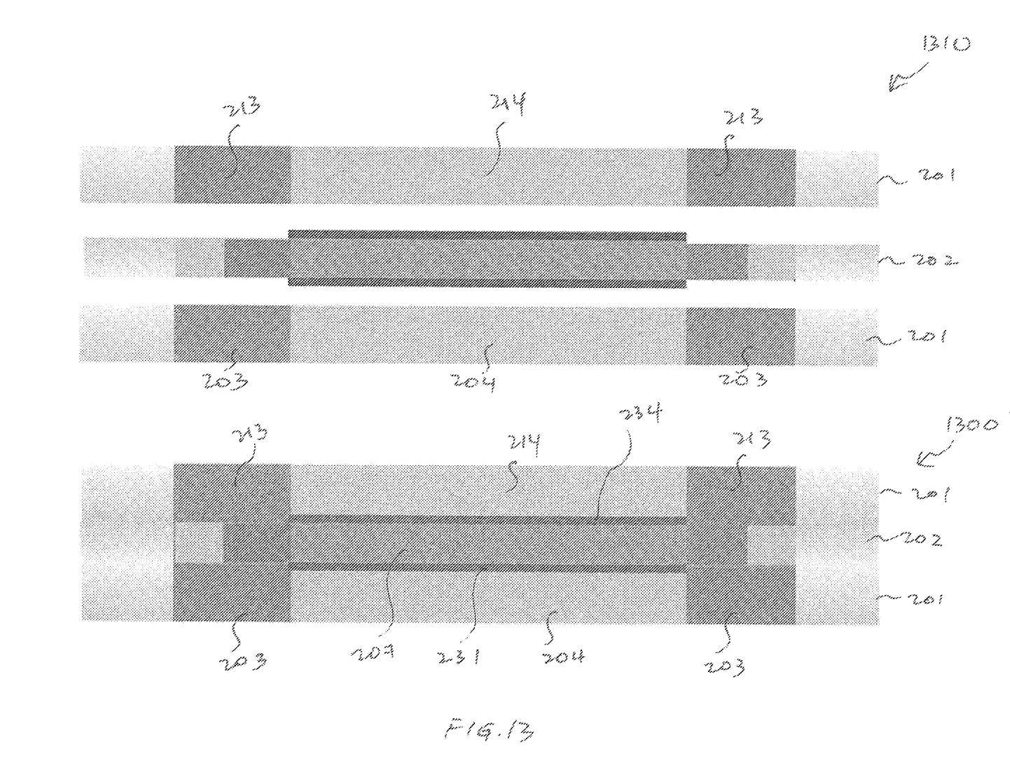

More details and aspects are mentioned in connection with the embodiments described above or below. The embodiments shown in FIG. 11 may comprise one or more optional additional features corresponding to one or more aspects mentioned in connection with the proposed concept or one or more embodiments described above (e.g. FIGS. 1 to 10) or below (e.g. FIGS. 12 to 15).

FIG. 12 shows a schematic illustration of a further semiconductor device 1200 according to an embodiment.

The semiconductor device 1200 may be similar to the semiconductor device described in connection with FIG. 11. In addition, the semiconductor device 1200 may include a further (second) laminar structure 211 arranged or placed (in 1210) on the second surface 209 of the semiconductor substrate. The second laminate structure 211 may be similar to the first laminate structure 201, for example. An electrically conductive structure 214 of the further laminar structure 214 may be arranged on or in electrical connection with an electrical contact structure 234 arranged at a second opposite surface 209 of the semiconductor substrate 202. For example, in a diode structure, the electrical contact structure 234 arranged at the second opposite surface 209 of the semiconductor substrate 202 may be electrically connected to a second doping region (of a second conductivity type, e.g. an n-type doping region) or cathode region of the diode structure.

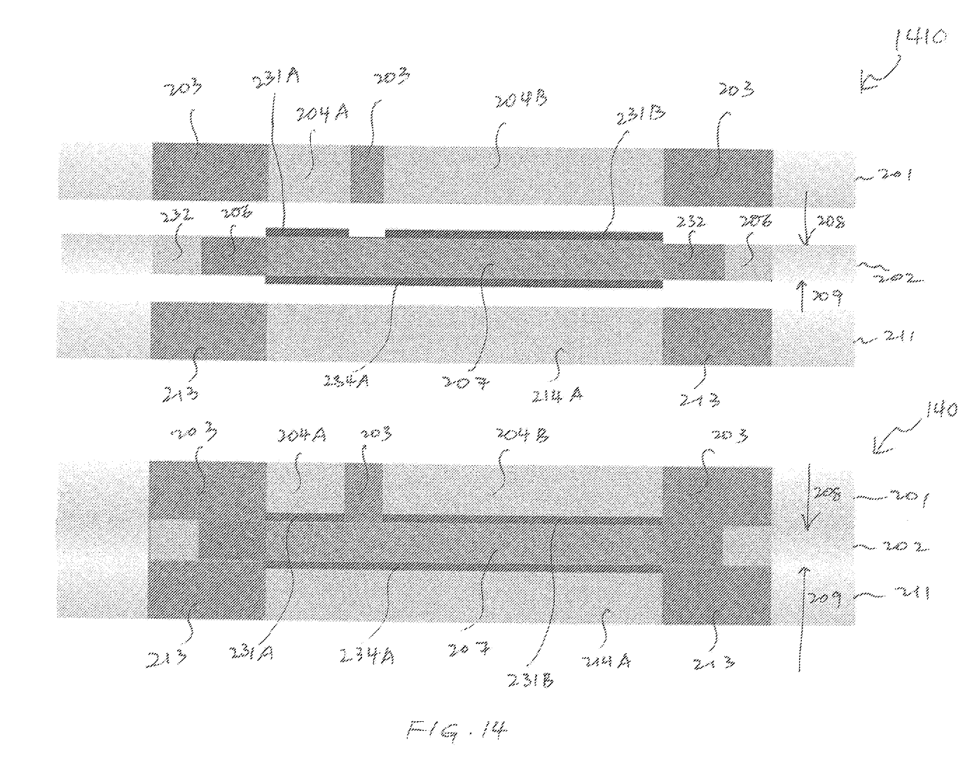

More details and aspects are mentioned in connection with the embodiments described above or below. The embodiments shown in FIG. 12 may comprise one or more optional additional features corresponding to one or more aspects mentioned in connection with the proposed concept or one or more embodiments described above (e.g. FIGS. 1 to 11) or below (e.g. FIGS. 13 to 15).

FIG. 13 shows a schematic illustration of a further semiconductor device 1300 according to an embodiment.

The semiconductor device 1300 may be similar to the semiconductor device described in connection with FIG. 12. The electrically conductive structures 204, 214 of the laminate structures 201, 211 arranged (in 1310) on opposite surfaces of the semiconductor wafer 202 may be copper vias, for example.

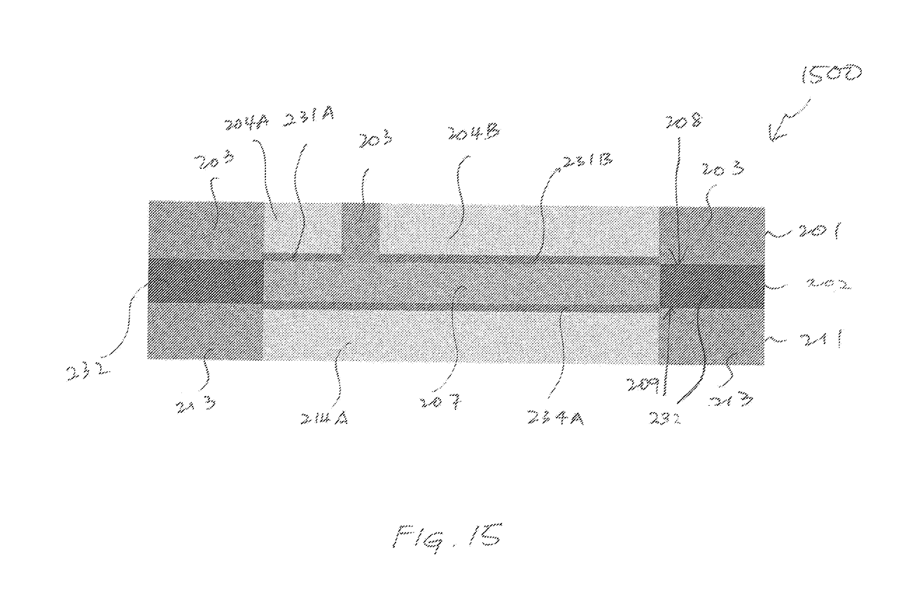

More details and aspects are mentioned in connection with the embodiments described above or below. The embodiments shown in FIG. 13 may comprise one or more optional additional features corresponding to one or more aspects mentioned in connection with the proposed concept or one or more embodiments described above (e.g. FIGS. 1 to 12) or below (e.g. FIGS. 14 to 15).

FIG. 14 shows a schematic illustration of a further semiconductor device 1400 according to an embodiment.

The semiconductor device 1400 may be similar to the semiconductor device described in connection with FIGS. 11 to 13, for example.

Additionally, optionally or alternatively, a first electrically conductive structure 204A of the laminar structure 201 may be arranged adjacent to a first electrical contact structure 231A of the semiconductor device structure 207. The first electrical contact structure 231A may be arranged or located on a first surface 208 of the semiconductor wafer 202, for example. For example, in a power transistor structure, the first electrical contact structure 231A may be electrically connected to an active first source/drain region of a MOSFET transistor structure or an active emitter region of a BJT transistor structure.

A second electrically conductive structure 204B of the laminar structure 201 may be arranged adjacent to a second electrical contact structure 231B of the semiconductor device structure 207. The second electrical contact structure 231B may be in electrical connection with a gate region or a base region of the semiconductor device structure 207, for example. For example, the second electrical contact structure 231B may be in electrical connection with a gate region of a MOSFET transistor structure or a base region of a BJT transistor structure. The first electrical contact structure 231A and the second electrical contact structure 231B of the semiconductor wafer 202 may be located arranged at or located at the first surface 208 of the semiconductor wafer 202, for example.

A first electrically conductive structure 214A of the further or second laminar structure 211 may be arranged on or in electrical connection with a third electrical contact structure 234A of the semiconductor device structure 207 arranged at a second opposite surface 209 of the semiconductor wafer 202.

The third electrical contact structure 234A of the semiconductor device structure 207 may be in electrical connection with a drain region of the semiconductor device structure 207. For example, in a power transistor structure, the third electrical contact structure 234A of the semiconductor device structure 207 may be electrically connected to an active second source/drain region of a MOSFET transistor structure or an active collector region of a BJT transistor structure.

More details and aspects are mentioned in connection with the embodiments described above or below. The embodiments shown in FIG. 14 may comprise one or more optional additional features corresponding to one or more aspects mentioned in connection with the proposed concept or one or more embodiments described above (e.g. FIGS. 1 to 13) or below (e.g. FIG. 15).

FIG. 15 shows a schematic illustration of a further semiconductor device 1500 according to an embodiment.

The semiconductor device 1500 may be similar to the semiconductor device described in connection with FIG. 14, for example.

The laminar structure 201 may be a glass-metal wafer, for example. For example, the electrically insulating material 203 of the laminar structure 201 may be glass, for example. Additionally or optionally, the semiconductor substrate 202 may have a thickness of less than 50 μm, for example.

The semiconductor devices (e.g. 265, 1000 1100, 1200, 1300, 1400, and 1500) may be connected to a printed circuit board via electrically conductive structures of a laminar structure arranged at a top side of the semiconductor device, for example. Additionally or optionally, the semiconductor devices (e.g. 265, 1000 1100, 1200, 1300, 1400, and 1500) may be connected to a cooling body via at least one electrically conductive structure of a laminar structure arranged at a bottom (back) side of the semiconductor device, for example.

More details and aspects are mentioned in connection with the embodiments described above or below. The embodiments shown in FIG. 15 may comprise one or more optional additional features corresponding to one or more aspects mentioned in connection with the proposed concept or one or more embodiments described above (e.g. FIGS. 1 to 14) or below.

Various examples relate to a front end process for extremely thick metal stacks on a wafer surface, for example. Various examples relate to front end wafer level thin chip packaging, for example. Various examples relate to a production of a laminate with accuracy, for example. Various examples related to a simple wafer level lamination process, for example.

Aspects and features (e.g. the semiconductor wafer, the semiconductor device structures, the laminar structure, the electrically conductive structures, and the electrically conductive material) mentioned in connection with one or more specific examples may be combined with one or more of the other examples.

Example embodiments may further provide a computer program having a program code for performing one of the above methods, when the computer program is executed on a computer or processor. A person of skill in the art would readily recognize that acts of various above-described methods may be performed by programmed computers. Herein, some example embodiments are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. Further example embodiments are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

Functional blocks denoted as “means for . . . ” (performing a certain function) shall be understood as functional blocks comprising circuitry that is configured to perform a certain function, respectively. Hence, a “means for s.th.” may as well be understood as a “means configured to or suited for s.th.”. A means configured to perform a certain function does, hence, not imply that such means necessarily is performing the function (at a given time instant).

Functions of various elements shown in the figures, including any functional blocks labeled as “means”, “means for providing a sensor signal”, “means for generating a transmit signal.”, etc., may be provided through the use of dedicated hardware, such as “a signal provider”, “a signal processing unit”, “a processor”, “a controller”, etc. as well as hardware capable of executing software in association with appropriate software. Moreover, any entity described herein as “means”, may correspond to or be implemented as “one or more modules”, “one or more devices”, “one or more units”, etc. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

What is claimed is:

1. A method for forming semiconductor devices, the method comprising:
placing a laminar structure comprising electrically insulating material arranged between a plurality of electrically conductive structures onto a surface of a semiconductor wafer comprising a plurality of semiconductor device structures, wherein
an electrically conductive structure of the plurality of electrically conductive structures is located adjacent to a semiconductor device structure of the plurality of semiconductor device structures, and
each electrically conductive structure of the plurality of electrically conductive structures extends from a first surface of the laminar structure towards a second opposite surface of the laminar structure.

2. The method according to claim 1, wherein each electrically conductive structure of the plurality of electrically conductive structures has a maximal lateral dimension of more than 10 μm.

3. The method according to claim 1, wherein the electrically conductive structures of the plurality of electrically conductive structures are metallic structures.

4. The method according to claim 1, wherein the electrically conductive structures of the plurality of electrically conductive structures extend from the first surface of the laminar structure to the second opposite surface of the laminar structure.

5. The method according to claim 1, wherein the electrically insulating material comprises a polymer based laminate or glass.

6. The method according to claim 1, wherein the laminar structure has a thickness of between 10 μm and 500 μm.

7. The method according to claim 1, wherein an arrangement of the plurality of electrically conductive structures in the laminar structure corresponds to an arrangement of a plurality of electrical contact structures of the plurality of semiconductor device structures at the surface of the semiconductor wafer.

8. The method according to claim 1, wherein placing the laminar structure onto the surface of the semiconductor wafer comprises arranging the electrically conductive structure of the plurality of electrically conductive structures onto an electrical contact structure arranged at an active area of the semiconductor device structure.

9. The method according to claim 1, wherein placing the laminar structure onto the surface of the semiconductor wafer comprises arranging the electrically insulating material of the laminar structure at scribe line regions of the semiconductor wafer between the plurality of semiconductor device structures.

10. The method according to claim 1, wherein placing the laminar structure onto the surface of the semiconductor wafer comprises arranging a first electrically conductive structure of the laminar structure onto a first electrical contact structure of the semiconductor device structure, wherein the first electrical contact structure is in electrical connection with a source region or emitter region of a semiconductor device transistor structure or a first anode region or cathode region of a semiconductor device diode structure.

11. The method according to claim 10, wherein placing the laminar structure onto the surface of the semiconductor wafer comprises arranging a second electrically conductive structure of the laminar structure onto a second electrical contact structure of the semiconductor device structure, wherein the second electrical contact structure is in electrical connection with a gate region or base region of the semiconductor device transistor structure.

12. The method according to claim 1, further comprising soldering the plurality of electrically conductive structures of the laminar structure to electrical contact structures of the plurality of semiconductor device structure.

13. The method according to claim 1, further comprising placing a die-attach wafer comprising a plurality of die-attach regions between the laminar structure and the semiconductor wafer, so that a die-attach region of the plurality of die-attach regions is arranged between the electrically conductive structure of the plurality of electrically conductive structures and an electrical contact structure of the semiconductor device structure.

14. The method according to claim 1, further comprising grinding an opposite further surface of the semiconductor wafer so that the semiconductor wafer has a desired thickness.

15. The method according to claim 1, further comprising grinding the laminar structure to expose the electrically conductive structures at the second opposite surface of the laminar structure.

16. The method according to claim 1, further comprising placing a further laminar structure comprising electrically insulating material arranged between a plurality of electrically conductive structures onto an opposite further surface of the semiconductor wafer comprising the plurality of semiconductor device structures, so that an electrically conductive structure of the plurality of electrically conductive structures of the further laminar structure is located adjacent to the semiconductor device structure of the plurality of semiconductor device structures,
wherein each electrically conductive structure of the plurality of electrically conductive structures of the further laminar structure extends from a first surface of the further laminar structure towards a second opposite surface of the further laminar structure.

17. The method according to claim 1, wherein placing the laminar structure onto the surface of the semiconductor wafer comprises rolling the laminar structure onto the surface of the semiconductor wafer.

18. A semiconductor device, comprising:
a semiconductor device structure formed in a semiconductor substrate; and
a polymer-based or glass-based electrically insulating laminar structure laterally surrounding an electrically conductive structure.

19. A method for forming a semiconductor device, the method comprising
rolling a laminar structure onto a surface of a semiconductor wafer that comprises a plurality of semiconductor device structures; and
forming a completed semiconductor device from the semiconductor wafer, wherein the completed semiconductor device comprises at least a part of the laminar structure.
